(19) United States
(12) Patent Application Publication
(10) Pub. No.: US 2025/0301629 A1
(43) Pub. Date: Sep. 25, 2025

(54) OXIDE SEMICONDUCTOR-BASED DYNAMIC RANDOM ACCESS MEMORY (DRAM) DEVICE

(71) Applicant: Kioxia Corporation, Tokyo (JP)

(72) Inventors: Akifumi GAWASE, Kuwana Mie (JP); Yusuke MIKI, Yokkaichi Mie (JP); Tomoki HARADA, Yokkaichi Mie (JP); Kazuhiro KATONO, Mie Mie (JP); Daisuke WATANABE, Kai Yamanashi (JP); Yusuke MUTO, Yokkaichi Mie (JP); Shusaku UKAI, Yokkaichi Mie (JP)

(21) Appl. No.: 19/065,286

(22) Filed: Feb. 27, 2025

(30) Foreign Application Priority Data
Mar. 22, 2024 (JP) 2024-046150

(51) Int. Cl. H10B 12/00; H10D 1/68; H10D 30/63; H10D 62/80; H10D 64/23; H10D 64/62

(52) U.S. Cl. CPC H10B 12/33; H10D 1/696; H10D 1/714; H10D 1/716; H10D 30/63; H10D 62/875; H10D 64/252; H10D 64/62; H10B 12/036; H10B 12/05

(57) ABSTRACT

According to one embodiment, a semiconductor memory device includes a first capacitor including a first electrode, a second electrode, and a first capacitor insulating film provided between the first electrode and the second electrode, and a first transistor including a first oxide semiconductor layer electrically connected to the second electrode and extending in a first direction, a first gate electrode provided next to the first oxide semiconductor layer, and a third electrode electrically connected to the first oxide semiconductor layer and provided on the opposite side of the second electrode. The second electrode includes a first portion, a second portion provided between the first portion and the first oxide semiconductor layer, and a third portion provided between the second portion and the first oxide semiconductor layer. A first width of the first portion in a second direction perpendicular to the first direction is smaller than a second width of the second portion in the second direction, and a third width of the third portion in the second direction is smaller than the second width.

### CROSS-REFERENCE TO RELATED APPLICATION

This application is based upon and claims the benefit of priority from Japanese Patent Application No. 2024-046150, filed Mar. 22, 2024, the entire contents of which are incorporated herein by reference.

### FIELD

Embodiments described herein relate generally to a semiconductor memory device.

### BACKGROUND

An oxide semiconductor transistor forming a channel in an oxide semiconductor layer has excellent characteristics that a channel leakage current during an off operation is extremely small. For this reason, for example, an oxide semiconductor transistor can be applied to a switching transistor in a memory cell of a dynamic random access memory (DRAM). When the oxide semiconductor transistor is applied to the switching transistor in the memory cell, an oxide semiconductor layer of the oxide semiconductor transistor is electrically connected (e.g., electrically coupled) to a storage node electrode of a capacitor.

Examples of related art include US-A-2022/0285350.

### DESCRIPTION OF THE DRAWINGS

FIG. 1 is an equivalent circuit diagram of a semiconductor memory device according to a first embodiment.

FIG. 2 is a schematic cross-sectional view of the semiconductor memory device according to the first embodiment.

FIG. 3 is a schematic cross-sectional view of the semiconductor memory device according to the first embodiment.

FIG. 4 is a schematic cross-sectional view of the semiconductor memory device according to the first embodiment.

FIG. 5 is a schematic enlarged cross-sectional view of the semiconductor memory device according to the first embodiment.

FIG. 6 is a schematic enlarged cross-sectional view of the semiconductor memory device according to the first embodiment.

FIG. 7 is a schematic cross-sectional view showing an example of a manufacturing method for the semiconductor memory device according to the first embodiment.

FIG. 8 is a schematic cross-sectional view showing an example of a manufacturing method for the semiconductor memory device according to the first embodiment.

FIG. 9 is a schematic cross-sectional view showing an example of the manufacturing method for the semiconductor memory device according to the first embodiment.

FIG. 10 is a schematic cross-sectional view showing an example of the manufacturing method for the semiconductor memory device according to the first embodiment.

FIG. 11 is a schematic cross-sectional view showing an example of the manufacturing method for the semiconductor memory device according to the first embodiment.

FIG. 12 is a schematic cross-sectional view showing an example of the manufacturing method for the semiconductor memory device according to the first embodiment.

FIG. 13 is a schematic cross-sectional view showing an example of the manufacturing method for the semiconductor memory device according to the first embodiment.

FIG. 14 is a schematic cross-sectional view showing an example of the manufacturing method for the semiconductor memory device according to the first embodiment.

FIG. 15 is a schematic cross-sectional view of a semiconductor memory device according to a comparative embodiment.

FIG. 16 is a schematic cross-sectional view of a semiconductor memory device according to a first modification example of the first embodiment.

FIG. 17 is a schematic enlarged cross-sectional view of the semiconductor memory device according to the first modification example of the first embodiment.

FIG. 18 is a schematic cross-sectional view of a semiconductor memory device according to a second modification example of the first embodiment.

FIG. 19 is a schematic cross-sectional view of the semiconductor memory device according to the second modification example of the first embodiment.

FIG. 20 is a schematic cross-sectional view of a semiconductor memory device according to a second embodiment.

FIG. 21 is a schematic cross-sectional view of the semiconductor memory device according to the second embodiment.

FIG. 22 is a schematic enlarged cross-sectional view of the semiconductor memory device according to the second embodiment.

FIG. 23 is a schematic cross-sectional view showing an example of a manufacturing method for the semiconductor memory device according to the second embodiment.

FIG. 24 is a schematic cross-sectional view showing an example of the manufacturing method for the semiconductor memory device according to the second embodiment.

FIG. 25 is a schematic cross-sectional view showing an example of the manufacturing method for the semiconductor memory device according to the second embodiment.

FIG. 26 is a schematic cross-sectional view showing an example of the manufacturing method for the semiconductor memory device according to the second embodiment.

FIG. 27 is a schematic cross-sectional view showing an example of the manufacturing method for the semiconductor memory device according to the second embodiment.

FIG. 28 is a schematic cross-sectional view showing an example of the manufacturing method for the semiconductor memory device according to the second embodiment.

FIG. 29 is a schematic cross-sectional view showing an example of the manufacturing method for the semiconductor memory device according to the second embodiment.

### DETAILED DESCRIPTION

Embodiments provide a semiconductor memory device including an oxide semiconductor transistor.

In general, according to one embodiment, a semiconductor memory device includes a first capacitor that includes a first electrode, a second electrode, and a first capacitor insulating film provided between the first electrode and the second electrode, and a first transistor that includes a first oxide semiconductor layer electrically connected (also referred to as “electrically coupled” and/or “communicably coupled”) to the second electrode and extending in a first direction, a first gate electrode provided next to (e.g., positioned adject to, extending along at least a portion of the length of, and/or surrounding) the first oxide semiconductor layer, a first gate insulating film provided between the first gate electrode and the first oxide semiconductor layer, and a third electrode electrically connected to the first oxide semiconductor layer and provided with the first oxide semiconductor layer between the second electrode and the third electrode, in which the second electrode includes a first portion, a second portion provided between the first portion and the first oxide semiconductor layer, and a third portion provided between the second portion and the first oxide semiconductor layer, a first width of the first portion in a second direction perpendicular to the first direction is smaller than a second width of the second portion in the second direction, and a third width of the third portion in the second direction is smaller than the second width.

Hereinafter, embodiments of the present disclosure will be described with reference to the drawings. In the following description, the same or similar members are given the same reference numerals, and the description of members that have already been described may be omitted as appropriate.

In this specification, the terms “upper”, “lower”, “upper portion”, “lower portion”, “above”, and “below” may be used for convenience. The terms “upper”, “lower”, “upper portion”, “lower portion”, “above”, and “below” merely indicate a relative positional relationship in the drawings, and do not define a positional relationship with respect to gravity.

In this specification, qualitative and quantitative analysis of chemical composition of members that configure a semiconductor memory device can be performed using, for example, secondary ion mass spectrometry (SIMS), energy dispersive x-ray spectroscopy (EDX), Rutherford back-scattering spectroscopy (RBS), or other methods. It is possible to measure the thicknesses of the members configuring the semiconductor memory device, distances between the members, crystal grain sizes, crystal orientation, and the like using, for example, a transmission electron microscope (TEM). It is also possible to measure the crystal orientation using, for example, a nano beam electron diffraction (NBED).

### First Embodiment

A semiconductor memory device according to a first embodiment includes a first capacitor and a first transistor. The first capacitor includes a first electrode, a second electrode, and a first capacitor insulating film provided between the first electrode and the second electrode. The first transistor includes a first oxide semiconductor layer electrically connected to the second electrode and extending in a first direction, a first gate electrode provided next to the first oxide semiconductor layer, a first gate insulating film provided between the first gate electrode and the first oxide semiconductor layer, and a third electrode electrically connected to the first oxide semiconductor layer and provided with the first oxide semiconductor layer between the second electrode and the third electrode. The second electrode includes a first portion, a second portion provided between the first portion and the first oxide semiconductor layer, and a third portion provided between the second portion and the first oxide semiconductor layer. A first width of the first portion in a second direction perpendicular to the first direction is smaller than a second width of the second portion in the second direction, and a third width of the third portion in the second direction is smaller than the second width. Some implementations relate to a semiconductor memory system, including a memory cell array forming a plurality of memory cells. At least one memory cell including a first capacitor comprising a first electrode, a second electrode, and a first capacitor insulating film provided between the first electrode and the second electrode. At least one memory cell including a first transistor comprising a first oxide semiconductor layer electrically connected to the second electrode and extending in a first direction, a first gate electrode provided next to the first oxide semiconductor layer, a first gate insulating film provided between the first gate electrode and the first oxide semiconductor layer, and a third electrode electrically connected to the first oxide semiconductor layer and provided with the first oxide semiconductor layer between the second electrode and the third electrode.

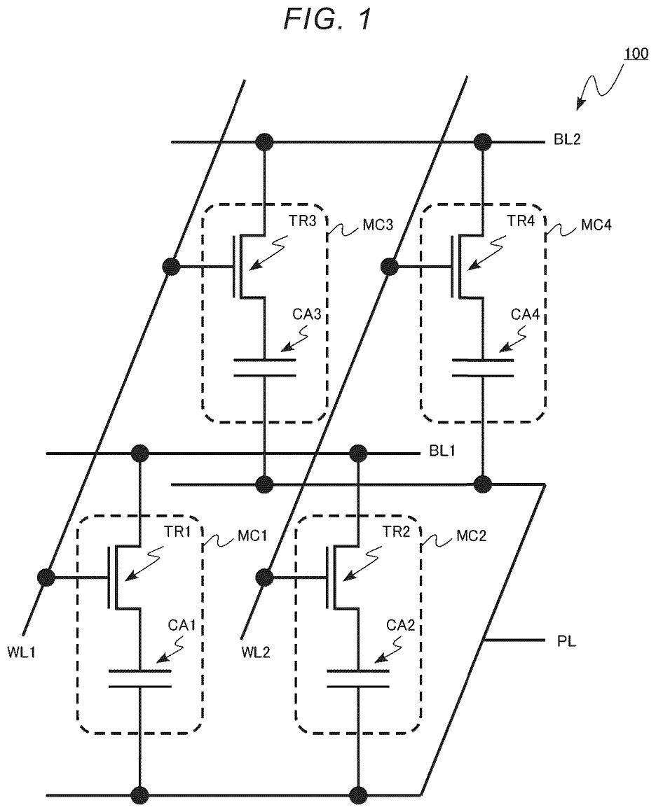

FIG. 1 is an equivalent circuit diagram of the semiconductor memory device according to the first embodiment. The semiconductor memory device according to the first embodiment is a semiconductor memory 100. The semiconductor memory 100 of the first embodiment is a DRAM. The semiconductor memory 100 uses oxide semiconductor transistors as switching transistors of memory cells of the DRAM.

FIG. 1 is a diagram showing a portion of a memory cell array in the semiconductor memory 100. A plurality of memory cells are disposed in the memory cell array. FIG. 1 shows a case where there are four memory cells, but the number of memory cells in the memory cell array is not limited to four. The semiconductor memory 100 can be a system including a memory cell array configured to store and retrieve data.

The memory cell array of the semiconductor memory 100 (also referred to herein as “semiconductor memory system 100”) includes a plurality of memory cells MC1, MC2, MC3, and MC4, a plurality of word lines WL1 and WL2, a plurality of bit lines BL1 and BL2, and a plate line PL. The first memory cell MC1 includes a first transistor TR1 and a first capacitor CA1. The second memory cell MC2 includes a second transistor TR2 and a second capacitor CA2. The third memory cell MC3 includes a third transistor TR3 and a third capacitor CA3. The fourth memory cell MC4 includes a fourth transistor TR4 and a fourth capacitor CA4.

Hereinafter, one of the plurality of memory cells MC1, MC2, MC3, and MC4, or the plurality of memory cells MC1, MC2, MC3, and MC4 collectively may be referred to simply as a memory cell MC. In addition, one of the plurality of word lines WL1 and WL2, or the plurality of word lines WL1 and WL2 collectively may be referred to simply as a word line WL. In addition, one of the plurality of bit lines BL1 and BL2, or the bit lines BL1 and BL2 collectively may be referred to simply as a bit line BL.

Hereinafter, one of the first transistor TR1, the second transistor TR2, the third transistor TR3, and the fourth transistor TR4, or the first transistor TR1, the second transistor TR2, the third transistor TR3, and the fourth transistor TR4 collectively may be referred to simply as a transistor TR. In addition, one of the first capacitor CA1, the second capacitor CA2, the third capacitor CA3, and the fourth capacitor CA4, or the first capacitor CA1, the second capacitor CA2, the third capacitor CA3, and the fourth capacitor CA4 collectively may be referred to simply as a capacitor CA.

The word line WL is electrically connected to a gate electrode of the transistor TR. The bit line BL is electrically connected to one of source/drain electrodes of the transistor TR. The other of the source/drain electrodes of the transistor TR is electrically connected to one electrode of the capacitor CA. The other electrode of the capacitor CA is connected to the plate line PL.

The memory cell MC stores data by accumulating charges in the capacitor CA. Data is written and read by turning on the transistor TR.

By selecting one bit line BL and one word line WL, one memory cell MC can be selected. For example, the transistor TR is turned on by applying a voltage to the word line WL in a state where a desired voltage is applied to the bit line BL, and data is written to the memory cell MC. In addition, for example, the transistor TR is turned on to detect a voltage change in the bit line BL corresponding to the amount of charges accumulated in the capacitor CA, and data is read from the memory cell MC.

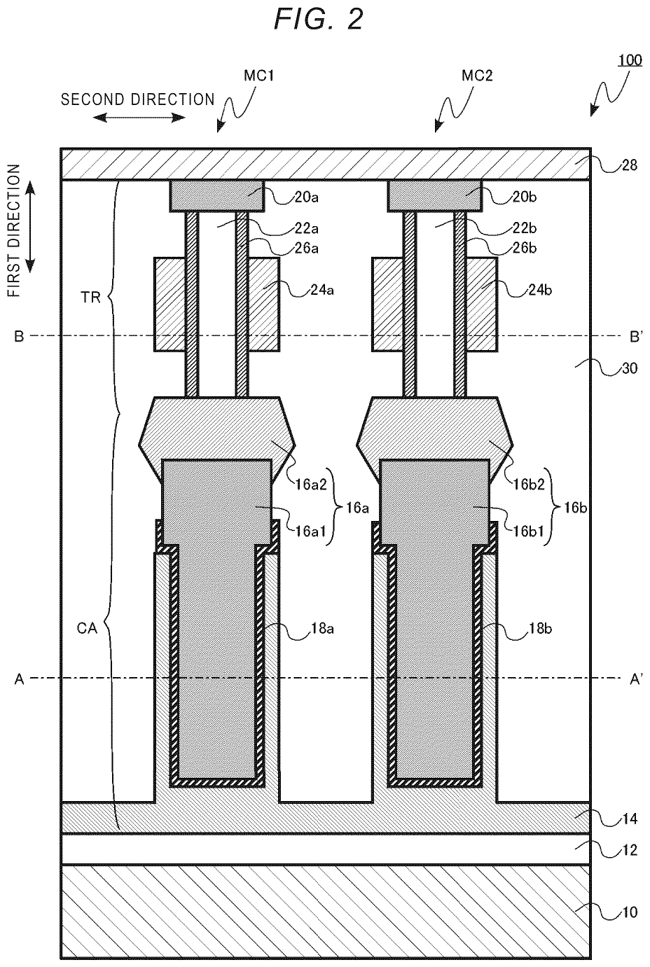

FIGS. 2, 3, and 4 are schematic cross-sectional views of the semiconductor memory device according to the first embodiment. FIG. 2 is a cross-sectional view including the first memory cell MC1 and the second memory cell MC2 in FIG. 1.

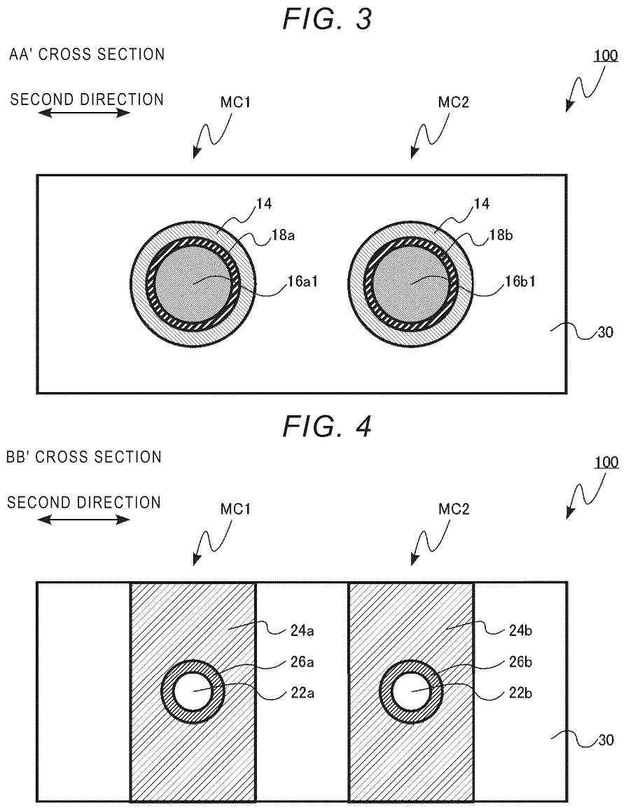

FIG. 3 is a cross-sectional view taken along line AA′ in FIG. 2. FIG. 4 is a cross-sectional view taken along line BB′ in FIG. 2. In FIG. 2, the vertical direction is referred to as a first direction. In FIG. 2, the horizontal direction is referred to as a second direction. The second direction is perpendicular to the first direction.

The semiconductor memory 100 according to the first embodiment includes a substrate 10, a substrate insulating layer 12, a plate electrode 14, a first storage node electrode 16a, a second storage node electrode 16b, a first capacitor insulating film 18a, a second capacitor insulating film 18b, a first source/drain electrode 20a, a second source/drain electrode 20b, a first oxide semiconductor layer 22a, a second oxide semiconductor layer 22b, a first gate electrode 24a, a second gate electrode 24b, a first gate insulating film 26a, a second gate insulating film 26b, a bit line 28, and an interlayer insulating layer 30.

The first storage node electrode 16a includes a first metal region 16a1 and a first oxide conductor region 16a2. In addition, the second storage node electrode 16b includes a second metal region 16b1 and a second oxide conductor region 16b2.

The plate electrode 14 is an example of a first electrode. The first storage node electrode 16a is an example of a second electrode. The second storage node electrode 16b is an example of a fourth electrode. The first source/drain electrode 20a is an example of a third electrode. The second source/drain electrode 20b is an example of a fifth electrode.

The first metal region 16a1 is an example of a first region. The first oxide conductor region 16a2 is an example of a second region.

Hereinafter, the first storage node electrode 16a and the second storage node electrode 16b may be collectively referred to as a storage node electrode 16. In addition, the first capacitor insulating film 18a and the second capacitor insulating film 18b may be collectively referred to as a capacitor insulating film 18. In addition, the first source/drain electrode 20a and the second source/drain electrode 20b may be collectively referred to as a source/drain electrode 20. In addition, the first oxide semiconductor layer 22a and the second oxide semiconductor layer 22b may be collectively referred to as an oxide semiconductor layer 22. In addition, the first gate electrode 24a and the second gate electrode 24b may be collectively referred to as a gate electrode 24. In addition, the first gate insulating film 26a and the second gate insulating film 26b may be collectively referred to as a gate insulating film 26.

The substrate 10 is, for example, a semiconductor substrate. The substrate 10 is, for example, a silicon substrate. For example, an insulating substrate can also be used as the substrate 10. The substrate 10 can also be omitted.

A memory cell array is provided on the substrate 10. The transistor TR and the capacitor CA are provided on the substrate 10. The capacitor CA is provided between the substrate 10 and the transistor TR.

The substrate insulating layer 12 is provided on the substrate 10. The substrate insulating layer 12 is provided between the substrate 10 and the plate electrode 14. The substrate insulating layer 12 is an insulator. The substrate insulating layer 12 is, for example, silicon oxide.

The capacitor CA includes the plate electrode 14, the storage node electrode 16, and the capacitor insulating film 18.

The plate electrode 14 is provided on the substrate insulating layer 12. The plate electrode 14 is a conductor. The plate electrode 14 contains, for example, a metal or a metal compound. The plate electrode 14 is, for example, titanium nitride.

The plate electrode 14 corresponds to the plate line PL in the equivalent circuit diagram of FIG. 1.

The storage node electrode 16 is provided on the plate electrode 14. The storage node electrode 16 extends in the first direction. The storage node electrode 16 is a conductor.

The first storage node electrode 16a includes, for example, a first metal region 16a1 and a first oxide conductor region 16a2. The second storage node electrode 16b includes, for example, a second metal region 16b1 and a second oxide conductor region 16b2.

The first oxide conductor region 16a2 is provided between the first metal region 16a1 and the first oxide semiconductor layer 22a. The first oxide conductor region 16a2 contacts (e.g., in in contact with) the first metal region 16a1 and the first oxide semiconductor layer 22a.

The second oxide conductor region 16b2 is provided between the second metal region 16b1 and the second oxide semiconductor layer 22b. The second oxide conductor region 16b2 contacts (e.g., in in contact with) the second metal region 16b1 and the second oxide semiconductor layer 22b.

The first metal region 16a1 and the second metal region 16b1 contain a metal or a metal compound. The first metal region 16a1 and the second metal region 16b1 are, for example, metal nitrides. The first metal region 16a1 and the second metal region 16b1 contain, for example, at least one metal element selected from the group including titanium (Ti), tantalum (Ta), tungsten (W), and molybdenum (Mo), and contain nitrogen (N). The first metal region 16a1 and the second metal region 16b1 are, for example, titanium nitride, tantalum nitride, tungsten nitride, or molybdenum nitride.

The first oxide conductor region 16a2 and the second oxide conductor region 16b2 include an oxide conductor. The chemical compositions of the first oxide conductor region 16a2 and the second oxide conductor region 16b2 are different from the chemical compositions of the first metal region 16a1 and the second metal region 16bl.

The first oxide conductor region 16a2 and the second oxide conductor region 16b2 contain, for example, at least one metal element selected from the group including indium (In), gallium (Ga), zinc (Zn), magnesium (Mg), aluminum (Al), manganese (Mn), tin (Sn), titanium (Ti), tantalum (Ta), calcium (Ca), tungsten (W), and molybdenum (Mo), and contain oxygen (O). The first oxide conductor region 16a2 and the second oxide conductor region 16b2 contain, for example, indium (In), tin (Sn), and oxygen (O). The first oxide conductor region 16a2 and the second oxide conductor region 16b2 contain, for example, indium tin oxide. The first oxide conductor region 16a2 and the second oxide conductor region 16b2 are, for example, indium tin oxide.

The first oxide conductor region 16a2 is, for example, polycrystalline. [111] directions of a plurality of crystals contained in the first oxide conductor region 16a2 are oriented in the first direction. Whether the [111] directions of the plurality of crystals contained in the first oxide conductor region 16a2 are oriented in the first direction is determined, for example, from an image obtained by a TEM. For example, angles between the [111] axes of the plurality of crystals and the first direction are calculated from an image of a cross section parallel to the first direction. When an average value of the calculated angles is within 20 degrees, the [111] directions of the plurality of crystals are deemed to be oriented in the first direction. Furthermore, whether the [111] directions of the plurality of crystals contained in the first oxide conductor region 16a2 are oriented in the first direction is determined, for example, from an electron diffraction pattern obtained by a nanobeam electron diffraction method. For example, when a diffraction spot intensity in the [111] direction is greater than diffraction spot intensities in other directions, the [111] directions of the plurality of crystals are deemed to be oriented in the first direction.

The second oxide conductor region 16b2 is, for example, polycrystalline. [111] directions of a plurality of crystals contained in the second oxide conductor region 16b2 are oriented in the first direction.

The capacitor insulating film 18 is provided between the plate electrode 14 and the storage node electrode 16. The capacitor insulating film 18 contacts (e.g., in in contact with) the plate electrode 14 and the storage node electrode 16.

The capacitor insulating film 18 is an insulator. The capacitor insulating film 18 includes, for example, an insulator having a dielectric constant higher than that of silicon dioxide. The capacitor insulating film 18 includes, for example, a so-called high-k insulator.

The capacitor insulating film 18 contains, for example, zirconium oxide. The capacitor insulating film 18 has, for example, a stacked structure of zirconium oxide, aluminum oxide, and zirconium oxide.

The plate electrode 14 is provided outside the storage node electrode 16. As shown in FIG. 3, in the AA′ cross section perpendicular to the first direction, the plate electrode 14 surrounds the storage node electrode 16. In the AA′ cross section, the plate electrode 14 surrounds the capacitor insulating film 18. In the AA′ cross section, the capacitor insulating film 18 surrounds the storage node electrode 16.

The transistor TR includes the oxide semiconductor layer 22, the gate electrode 24, the gate insulating film 26, the storage node electrode 16, and the source/drain electrode 20. The storage node electrode 16 functions as a source/drain electrode of the transistor TR.

The oxide semiconductor layer 22 is provided on the storage node electrode 16. The oxide semiconductor layer 22 is provided between the storage node electrode 16 and the source/drain electrode 20.

The oxide semiconductor layer 22 is electrically connected to the storage node electrode 16 and the source/drain electrode 20. The oxide semiconductor layer 22 contacts (e.g., in in contact with), for example, the storage node electrode 16 and the source/drain electrode 20. The oxide semiconductor layer 22 extends in the first direction.

In the oxide semiconductor layer 22, a channel serving as a current path is formed when the transistor TR is turned on.

The oxide semiconductor layer 22 is an oxide semiconductor. The oxide semiconductor layer 22 is, for example, amorphous.

The oxide semiconductor layer 22 contains at least one metal element selected from the group including indium (In), gallium (Ga), zinc (Zn), magnesium (Mg), aluminum (Al), manganese (Mn), tin (Sn), titanium (Ti), calcium (Ca), and cadmium (Cd), and contains oxygen (O).

The oxide semiconductor layer 22 contains, for example, at least one element selected from the group including indium (In), gallium (Ga), silicon (Si), aluminum (Al), and tin (Sn), and contains zinc (Zn) and oxygen (O). The oxide semiconductor layer 22 contains, for example, indium (In), gallium (Ga), zinc (Zn), and oxygen (O). The oxide semiconductor layer 22 contains, for example, indium gallium zinc oxide. The oxide semiconductor layer 22 is, for example, indium gallium zinc oxide.

The oxide semiconductor layer 22 has, for example, a chemical composition different from the chemical compositions of the storage node electrode 16 and the source/drain electrode 20.

The oxide semiconductor layer 22 contains, for example, oxygen vacancies. The oxygen vacancies in the oxide semiconductor layer 22 function as donors.

The gate electrode 24 faces the oxide semiconductor layer 22. As shown in FIG. 4, the gate electrode 24 surrounds (e.g., is positioned on all sides of, enclosing, and/or encapsulating) the oxide semiconductor layer 22 in the BB′ cross section perpendicular to the first direction. For example, the gate electrode 24 extends continuously around the entire perimeter of the oxide semiconductor layer 22 in a cross-section perpendicular to the first direction, enclosing the oxide semiconductor layer 22 from all lateral sides and, in some implementations, extending in a conformal manner along the vertical extent of the oxide semiconductor layer 22 to provide uniform electrostatic control over the channel region formed within the oxide semiconductor layer 22. The gate electrode 24 is provided around the oxide semiconductor layer 22. The transistor TR is a so-called surrounding gate transistor (SGT).

The gate electrode 24 is a conductor. The gate electrode 24 is, for example, a metal, a metal compound, or a semiconductor. The gate electrode 24 contains, for example, tungsten (W). The gate electrode 24 is, for example, tungsten.

The gate electrodes 24 correspond to the word lines WL in the equivalent circuit diagram of FIG. 1. For example, the first gate electrode 24a corresponds to a first word line WL1. In addition, for example, the second gate electrode 24b corresponds to a second word line WL2.

The gate insulating film 26 is provided between (e.g., interposed in direct contact with and extending continuously around all lateral surfaces of the oxide semiconductor layer 22, separating the oxide semiconductor layer 22 from the gate electrodes 24 to electrically insulate the gate electrodes 24 while permitting capacitive coupling for gate control over the channel region) the oxide semiconductor layer 22 and the gate electrodes 24. As shown in FIG. 4, the gate insulating film 26 surrounds the oxide semiconductor layer 22 in the cross section BB′ perpendicular to the first direction. The gate insulating film 26 is provided between the storage node electrode 16 and the source/drain electrode 20. The gate insulating film 26 contacts (e.g., in in contact with), for example, the storage node electrode 16 and the source/drain electrode 20.

The gate insulating film 26 is an insulator. The gate insulating film 26 contains, for example, silicon (Si) and nitrogen (N). The gate insulating film 26 contains, for example, silicon nitride.

The source/drain electrode 20 is provided on the oxide semiconductor layer 22. The source/drain electrode 20 contacts (e.g., in in contact with) the oxide semiconductor layer 22. The source/drain electrode 20 is provided on the side of the oxide semiconductor layer 22 opposite the storage node electrode 16. The oxide semiconductor layer 22 is provided between (e.g., positioned such that it forms an electrical connection with both the storage node electrode 16 and the source/drain electrode 20, with its channel region extending between these electrodes to facilitate charge transport when the transistor is in an ON state, while also being isolated from direct electrical contact with the gate electrode 24 by the gate insulating film 26) the storage node electrode 16 and the source/drain electrode 20.

The source/drain electrode 20 includes, for example, an oxide conductor. The source/drain electrode 20 includes, for example, the same oxide conductor as the storage node electrode 16.

The source/drain electrode 20 contains, for example, at least one metal element selected from the group including indium (In), gallium (Ga), zinc (Zn), magnesium (Mg), aluminum (Al), manganese (Mn), tin (Sn), titanium (Ti), tantalum (Ta), calcium (Ca), tungsten (W), and molybdenum (Mo), and contains oxygen (O). The source/drain electrode 20 contains, for example, indium (In), tin (Sn), and oxygen (O). The source/drain electrode 20 contains, for example, indium tin oxide. The source/drain electrode 20 is, for example, indium tin oxide.

The bit line 28 is provided on the transistor TR. The bit line 28 extends in the second direction. The bit line 28 is provided on the source/drain electrode 20. The bit line 28 contacts (e.g., in in contact with) the source/drain electrode 20.

The bit line 28 is a conductor. The bit line 28 contains, for example, a metal or a metal compound. The bit line 28 contains, for example, at least one metal element selected from the group including titanium (Ti), tantalum (Ta), tungsten (W), and molybdenum (Mo). The bit line 28 has, for example, a stacked structure of titanium nitride and tungsten.

The bit line 28 corresponds to the bit line BL in the equivalent circuit diagram of FIG. 1. For example, the bit line 28 corresponds to a first bit line BL1.

The interlayer insulating layer 30 is provided around the memory cell MC. The interlayer insulating layer 30 is provided around, for example, the first memory cell MC1 and the second memory cell MC2.

The interlayer insulating layer 30 is an insulator. The interlayer insulating layer 30 contains, for example, silicon oxide.

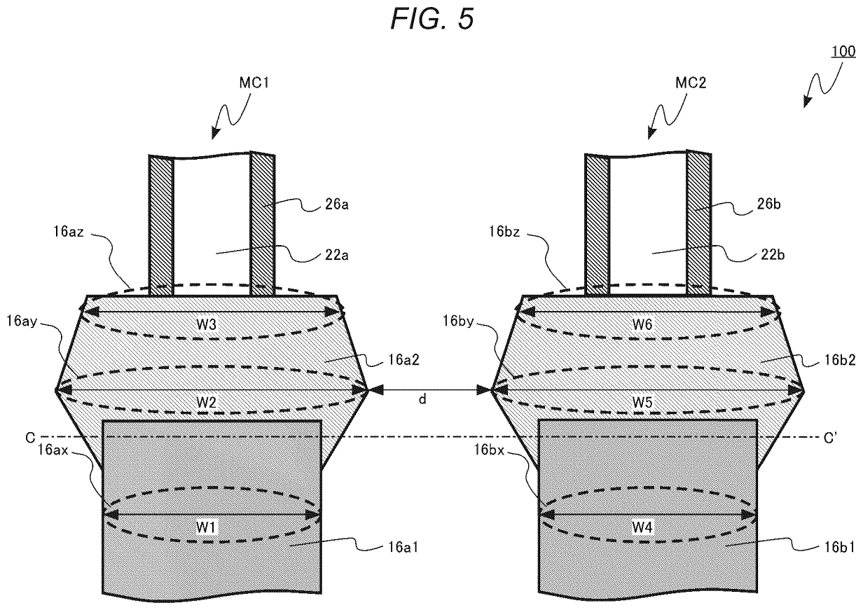

FIG. 5 is a schematic enlarged cross-sectional view of the semiconductor memory device according to the first embodiment. FIG. 5 is a schematic enlarged cross-sectional view of a portion of FIG. 1. FIG. 5 shows a portion of the storage node electrode 16, a portion of the oxide semiconductor layer 22, and a portion of the gate insulating film 26 of the first memory cell MC1 and the second memory cell MC2.

The first storage node electrode 16a includes a first portion 16ax, a second portion 16ay, and a third portion 16az. The second portion 16ay is provided between the first oxide semiconductor layer 22a and the first portion 16ax. The third portion 16az is provided between the first oxide semiconductor layer 22a and the second portion 16ay.

The third portion 16az is the uppermost portion of the first storage node electrode 16a. The third portion 16az contacts (e.g., in in contact with), for example, the first oxide semiconductor layer 22a.

A first width (W1 in FIG. 5) of the first portion 16ax in the second direction is smaller (e.g., the distance across the first portion 16ax along the second direction is reduced relative to the distance across the second portion 16ay, resulting in a narrower structure at the first portion 16ax compared to the second portion 16ay) than a second width (W2 in FIG. 5) of the second portion 16ay in the second direction. In addition, a third width (W3 in FIG. 5) of the third portion 16az in the second direction is smaller (e.g., the distance across the third portion 16az along the second direction is reduced relative to the second portion 16ay, forming a tapering or stepped structure where the third portion 16az is narrower than the second portion 16ay but may be wider than the first portion 16ax) than the second width W2.

The uppermost portion of the first storage node electrode 16a has a barrel shape in a cross section parallel to the first direction.

The first portion 16ax is located, for example, in the first metal region 16al. The second portion 16ay is located, for example, in the first oxide conductor region 16a2. The third portion 16az is located, for example, in the first oxide conductor region 16a2.

For example, the first width W1 is 0.5 times or more and 0.9 times or less the second width W2. In addition, for example, the third width W3 is 0.7 times or more and 0.95 times or less the second width W2. In addition, for example, the third width W3 is larger than the first width W1.

The second storage node electrode 16b includes a fourth portion 16bx, a fifth portion 16by, and a sixth portion 16bz. The fifth portion 16by is provided between the second oxide semiconductor layer 22b and the fourth portion 16bx. The sixth portion 16bz is provided between the second oxide semiconductor layer 22b and the fifth portion 16by.

The sixth portion 16bz is the uppermost portion of the second storage node electrode 16b. The sixth portion 16bz contacts (e.g., in in contact with), for example, the second oxide semiconductor layer 22b.

A fourth width (W4 in FIG. 5) of the fourth portion 16bx in the second direction is smaller than a fifth width (W5 in FIG. 5) of the fifth portion 16by in the second direction. In addition, a sixth width (W6 in FIG. 5) of the sixth portion 16bz in the second direction is smaller than the fifth width W5.

The upper portion of the second storage node electrode 16b has a barrel shape in a cross section parallel to the first direction.

The fourth portion 16bx is located, for example, in the second metal region 16b1. The fifth portion 16by is located, for example, in the second oxide conductor region 16b2. The sixth portion 16bz is located, for example, in the second oxide conductor region 16b2.

For example, the fourth width W4 is 0.5 times or more and 0.9 times or less the fifth width W5. In addition, for example, the sixth width W6 is 0.7 times or more and 0.95 times or less the fifth width W5. For example, the sixth width W6 is larger than the fourth width W4.

As shown in FIG. 5, the shortest distance (d in FIG. 5) between the first storage node electrode 16a and the second storage node electrode 16b in the second direction is smaller than, for example, the first width W1. In addition, as shown in FIG. 5, the shortest distance (d in FIG. 5) between the first storage node electrode 16a and the second storage node electrode 16b in the second direction is smaller than, for example, the fourth width W4.

The first oxide conductor region 16a2 covers, for example, the side surface of the first metal region 16al. In addition, the second oxide conductor region 16b2 covers, for example, the side surface of the second metal region 16bl.

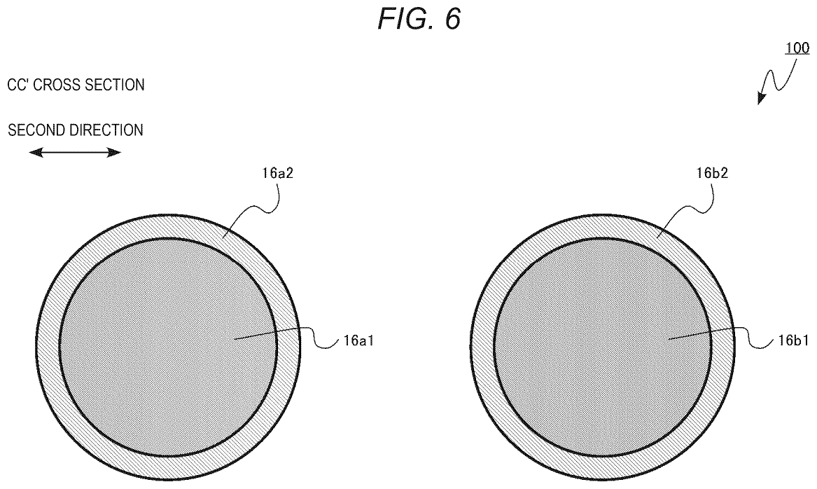

FIG. 6 is a schematic enlarged cross-sectional view of the semiconductor memory device according to the first embodiment. FIG. 6 shows a CC′ cross section of FIG. 5. The CC′ cross section is a cross section perpendicular to the first direction.

As shown in FIG. 6, for example, in the CC′ cross section, the first oxide conductor region 16a2 surrounds at least a portion of the first metal region 16al. In addition, as shown in FIG. 6, for example, in the CC′ cross section, the second oxide conductor region 16b2 surrounds at least a portion of the second metal region 16bl.

Next, an example of a manufacturing method for the semiconductor memory device according to the first embodiment will be described.

The manufacturing method for the semiconductor memory device according to the first embodiment includes forming a first pillar which has a stacked structure configured with a first conductor, an insulator, and a second conductor, of which at least an upper surface is the second conductor, and which protrudes from a periphery and extends in a first direction, and forming a second pillar which has a stacked structure configured with the first conductor, the insulator, and the second conductor, of which at least an upper surface is the second conductor, which protrudes from a periphery and extends in the first direction, and which is positioned in a second direction perpendicular to the first direction with respect to the first pillar, forming an oxide conductor on the upper surface of the first pillar and the upper surface of the second pillar so that the oxide conductor formed on the upper surface of the first pillar and the oxide conductor formed on the upper surface of the second pillar do not come into contact with each other, removing the corners of the upper surface of the oxide conductor formed on at least the upper surface of the first pillar, removing the corners of the upper surface of the oxide conductor formed on at least the upper surface of the second pillar, and burying an insulating film between the first pillar and the second pillar.

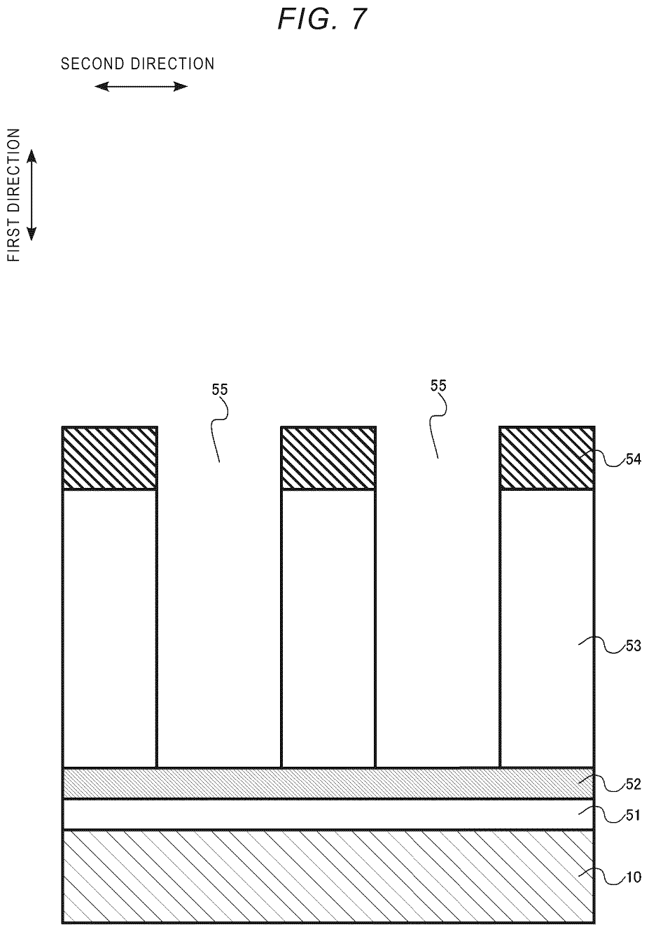

FIGS. 7, 8, 9, 10, 11, 12, 13, and 14 are schematic cross-sectional views showing an example of the manufacturing method for the semiconductor memory device according to the first embodiment. FIGS. 7 to 14 show cross sections corresponding to FIG. 2, respectively. FIGS. 7 to 14 are diagrams showing an example of a manufacturing method for the semiconductor memory 100.

Hereinafter, description will be given of an example of a case where the substrate insulating layer 12 is made of silicon oxide, the plate electrode 14 is made of titanium nitride, the metal region of the storage node electrode 16 is made of titanium nitride, the oxide conductor region of the storage node electrode 16 is made of indium tin oxide, the capacitor insulating film 18 is made of zirconium oxide, the source/drain electrode 20 is made of indium tin oxide, the oxide semiconductor layer 22 is made of indium gallium zinc oxide, the gate electrode 24 is made of tungsten, the gate insulating film 26 is made of silicon nitride, and the interlayer insulating layer 30 is made of silicon oxide.

First, a first silicon oxide film 51, a first titanium nitride film 52, a second silicon oxide film 53, and a first silicon nitride film 54 are formed on the substrate 10. The first silicon oxide film 51, the first titanium nitride film 52, the second silicon oxide film 53, and the first silicon nitride film 54 are formed, for example, by a chemical vapor deposition (CVD) method.

The first silicon oxide film 51 eventually becomes the substrate insulating layer 12. The first titanium nitride film 52 eventually becomes a portion of the plate electrode 14. The second silicon oxide film 53 eventually becomes a portion of the interlayer insulating layer 30.

Next, a first opening 55 that penetrates the first silicon nitride film 54 and the second silicon oxide film 53 and reaches the first titanium nitride film 52 is formed (FIG. 7). The first opening 55 is formed, for example, using a lithography method and a reactive ion etching method (RIE method).

Next, the first opening 55 is filled with a second titanium nitride film 56, a zirconium oxide film 57, and a third titanium nitride film 58. The second titanium nitride film 56, the zirconium oxide film 57, and the third titanium nitride film 58 are formed, for example, using an atomic layer deposition method (ALD method). The second titanium nitride film 56 is patterned in the first opening 55 before the zirconium oxide film 57 is formed.

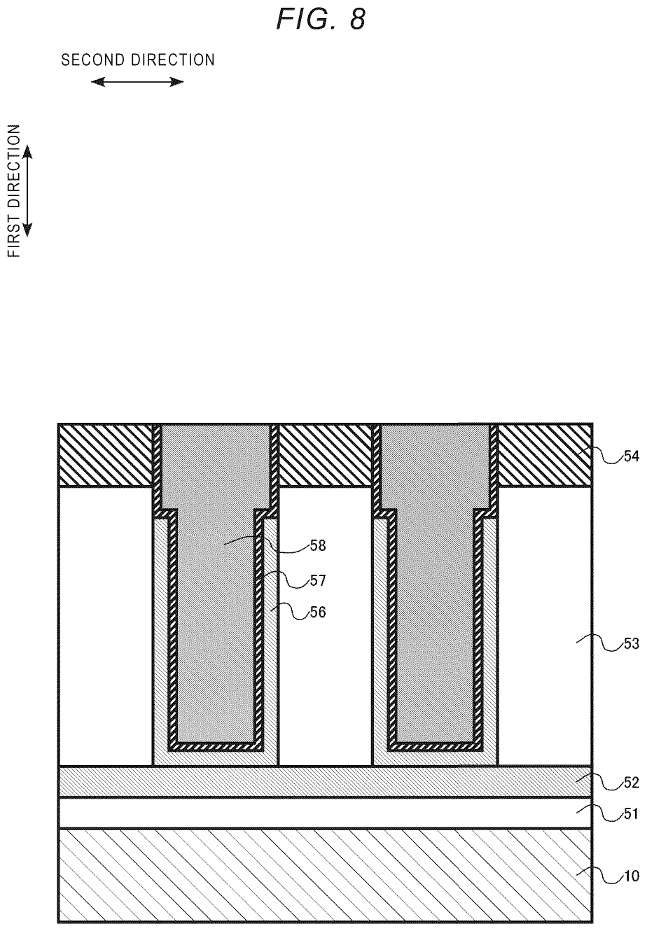

Next, the zirconium oxide film 57 and the third titanium nitride film 58 on the surface of the first silicon nitride film 54 are removed (FIG. 8). The zirconium oxide film 57 and the third titanium nitride film 58 are removed, for example, using a chemical mechanical polishing method (CMP method).

The second titanium nitride film 56 eventually becomes a portion of the plate electrode 14. The zirconium oxide film 57 eventually becomes the capacitor insulating film 18. The third titanium nitride film 58 eventually becomes a portion of the storage node electrode 16.

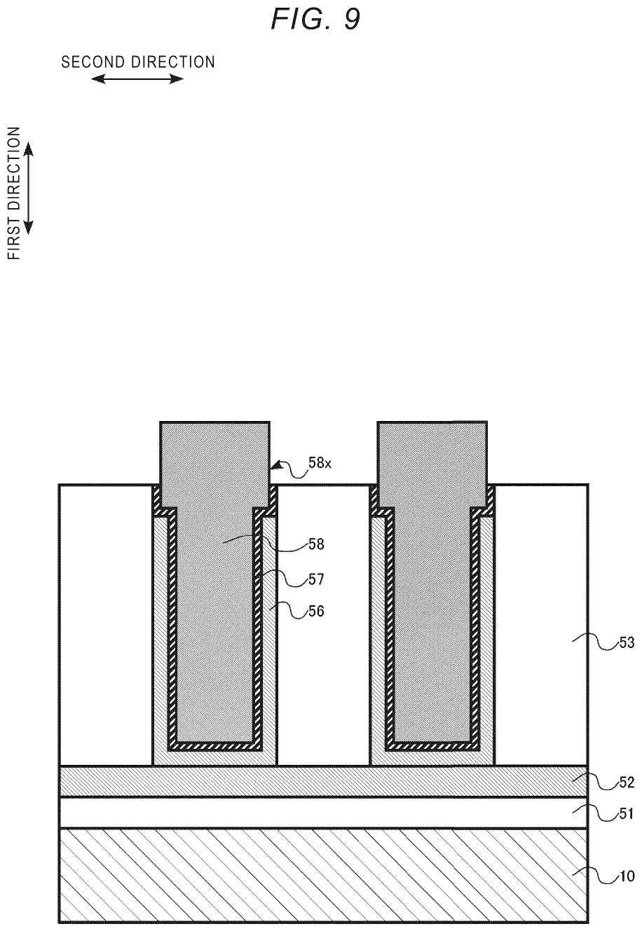

Next, the first silicon nitride film 54 and a portion of the zirconium oxide film 57 are removed (FIG. 9). The first silicon nitride film 54 and a portion of the zirconium oxide film 57 are removed, for example, by a wet etching method.

By removing the first silicon nitride film 54, a portion of the third titanium nitride film 58 protrudes from the upper surface of the second silicon oxide film 53. A pillar 58x of titanium nitride protruding from the surrounding insulator is formed.

The pillar 58x has a stacked structure of the second titanium nitride film 56, the zirconium oxide film 57, and the third titanium nitride film 58. The upper surface and side surface of the pillar 58x are made of titanium nitride.

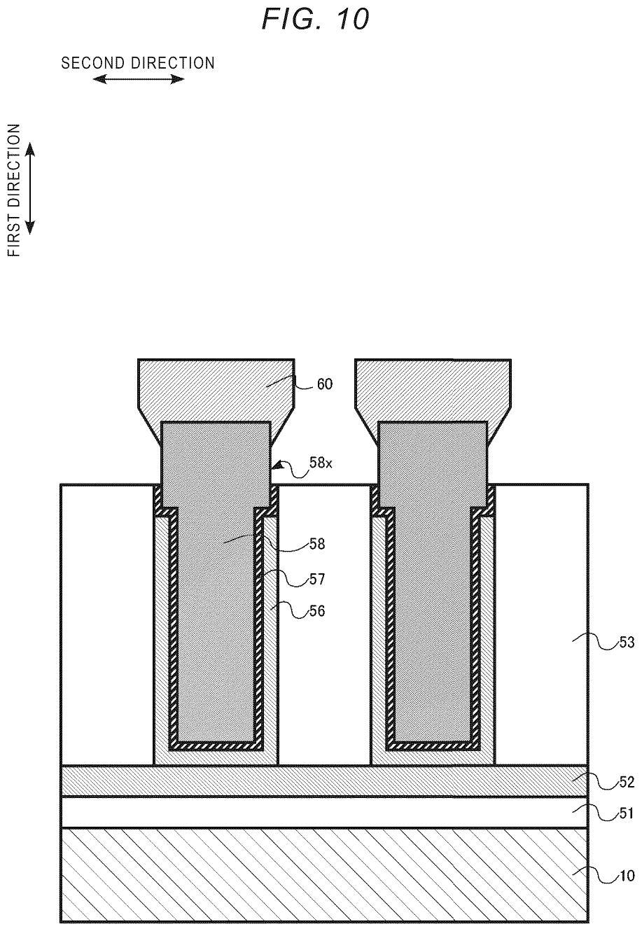

Next, an indium tin oxide film 60 is formed on the upper surface of the pillar 58x of the third titanium nitride film 58 (FIG. 10). The indium tin oxide film 60 is formed under a condition that a growth rate in the upward direction becomes higher than a growth rate in the lateral direction. The indium tin oxide film 60 is also formed under a condition that a step coverage is poor.

The width of the indium tin oxide film 60 formed on the upper surface of the pillar 58x in the second direction is larger than the width of the pillar 58x in the second direction. In addition, the indium tin oxide films 60 formed on the upper surfaces of two pillars 58x adjacent to each other in the second direction are formed not to come into contact with each other.

The indium tin oxide film 60 is formed under conditions that, for example, [111] directions of a plurality of crystals contained in the indium tin oxide film 60 are oriented in a direction perpendicular to the upper surface of the pillar 58x of the third titanium nitride film 58. The indium tin oxide film 60 is formed such that, for example, the [111] directions of the plurality of crystals contained in the indium tin oxide film 60 are oriented in the first direction. By forming the indium tin oxide film 60 such that the [111] directions of the plurality of crystals contained in the indium tin oxide film 60 are oriented in the first direction, a growth rate of the indium tin oxide film 60 in the upward direction becomes higher than a growth rate in the lateral direction.

For example, the indium tin oxide film 60 is formed to cover a portion of the side surface of the pillar 58x. The indium tin oxide film 60 is formed under a condition that a growth rate in the upward direction is high, and thus the indium tin oxide films 60 on two adjacent pillars 58x are prevented from coming into contact with each other. In addition, the indium tin oxide film 60 is formed under a condition that a step coverage is poor, and thus the indium tin oxide film 60 is hardly formed on the upper surface of the second silicon oxide film 53 between the two adjacent pillars 58x.

The indium tin oxide film 60 is formed, for example, by a physical vapor deposition (PVD) method, which has poor step coverage. The indium tin oxide film 60 is formed, for example, by a sputtering method, which has poor step coverage.

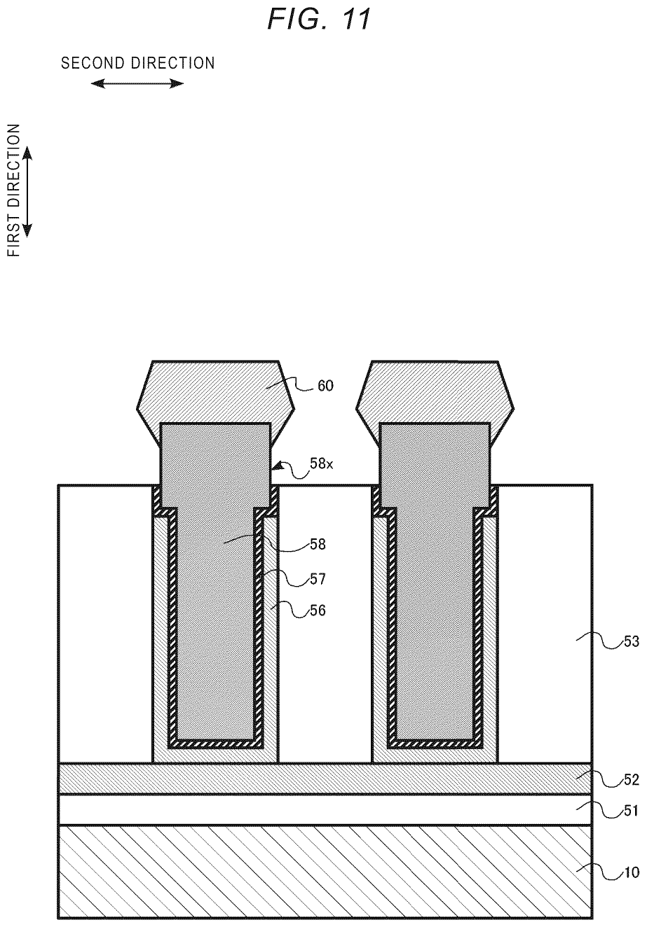

Next, the corners of the upper surface of the indium tin oxide film 60 are removed (FIG. 11). The corners of the upper surface of the indium tin oxide film 60 are formed into a forward tapered shape.

For example, the corners of the upper surface of the indium tin oxide film 60 are removed by an RIE method. In addition, for example, the corners of the upper surface of the indium tin oxide film 60 are removed by a wet etching method.

For example, even when the indium tin oxide film 60 is formed on the upper surface of the second silicon oxide film 53 between two pillars 58x, it is possible to remove the indium tin oxide film 60 by etching for removing the corners of the upper surface of the indium tin oxide film 60.

Next, a third silicon oxide film 61 is formed on the indium tin oxide film 60 and the second silicon oxide film 53. The third silicon oxide film 61 is formed, for example, by a CVD method. The corners of the upper surface of the indium tin oxide film 60 are formed into a forward tapered shape, which improves a burying property of the third silicon oxide film 61 between the two adjacent pillars 58x. The third silicon oxide film 61 eventually becomes a portion of the interlayer insulating layer 30.

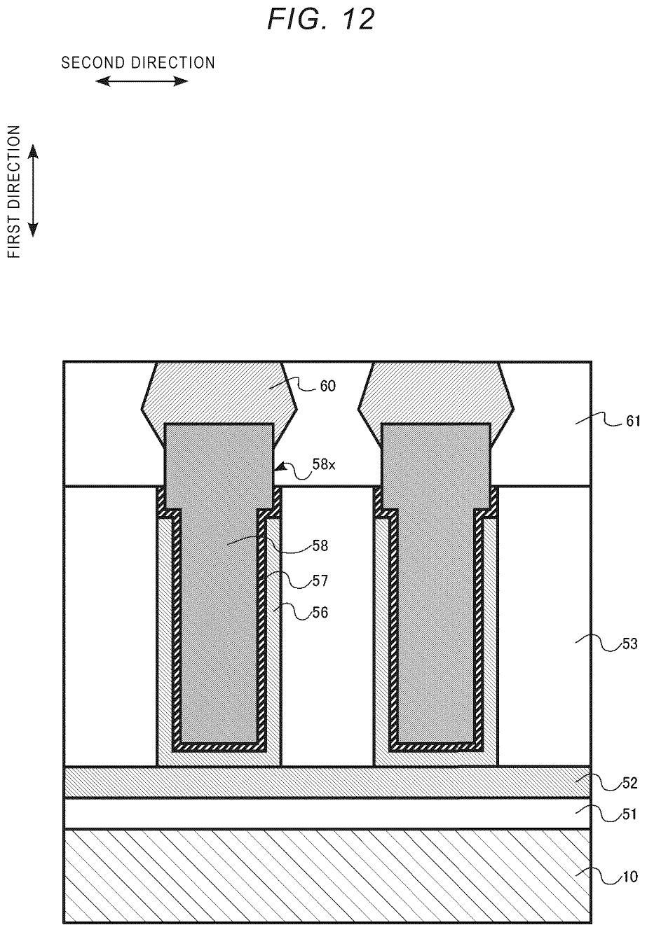

Next, the third silicon oxide film 61 on the indium tin oxide film 60 is removed (FIG. 12). The third silicon oxide film 61 is removed, for example, by a CMP method.

Next, a fourth silicon oxide film 62 is formed on the indium tin oxide film 60 and the third silicon oxide film 61. The fourth silicon oxide film 62 is formed, for example, by a CVD method. The fourth silicon oxide film 62 eventually becomes a portion of the interlayer insulating layer 30.

Next, a tungsten film 63 is formed on the fourth silicon oxide film 62. The tungsten film 63 is formed, for example, by a CVD method.

Next, the tungsten film 63 is patterned. The tungsten film 63 is patterned, for example, using a lithography method and an RIE method. The tungsten film 63 eventually becomes the gate electrode 24.

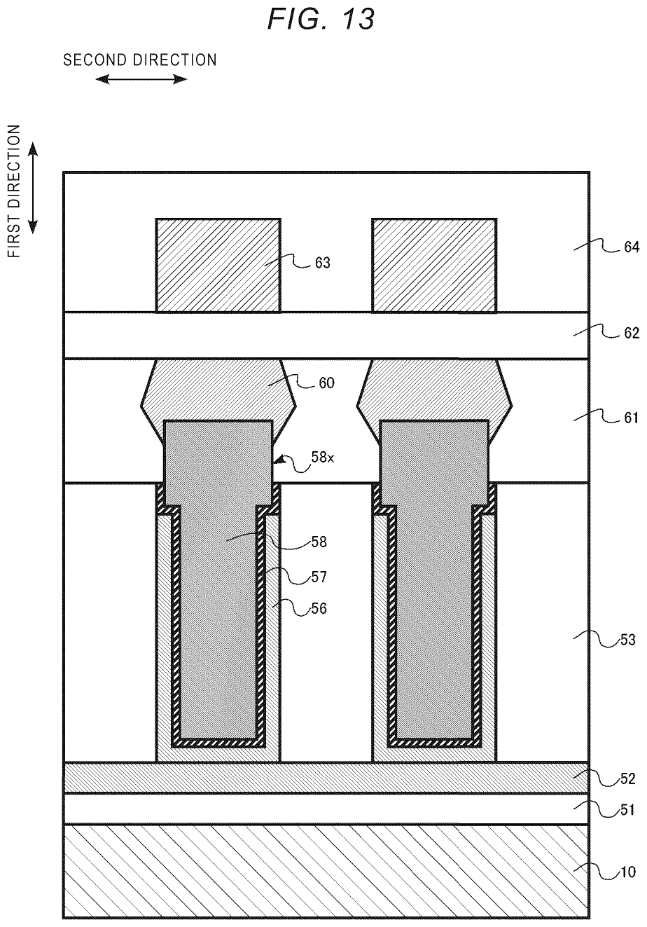

Next, a fifth silicon oxide film 64 is formed on the tungsten film 63 (FIG. 13). The fifth silicon oxide film 64 is formed, for example, by a CVD method. The fifth silicon oxide film 64 eventually becomes a portion of the interlayer insulating layer 30.

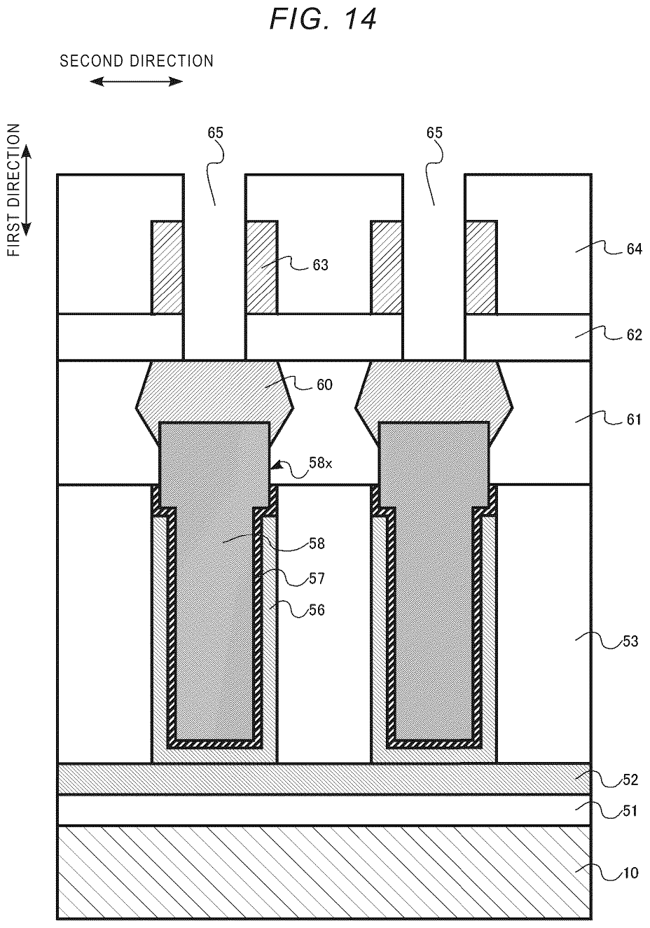

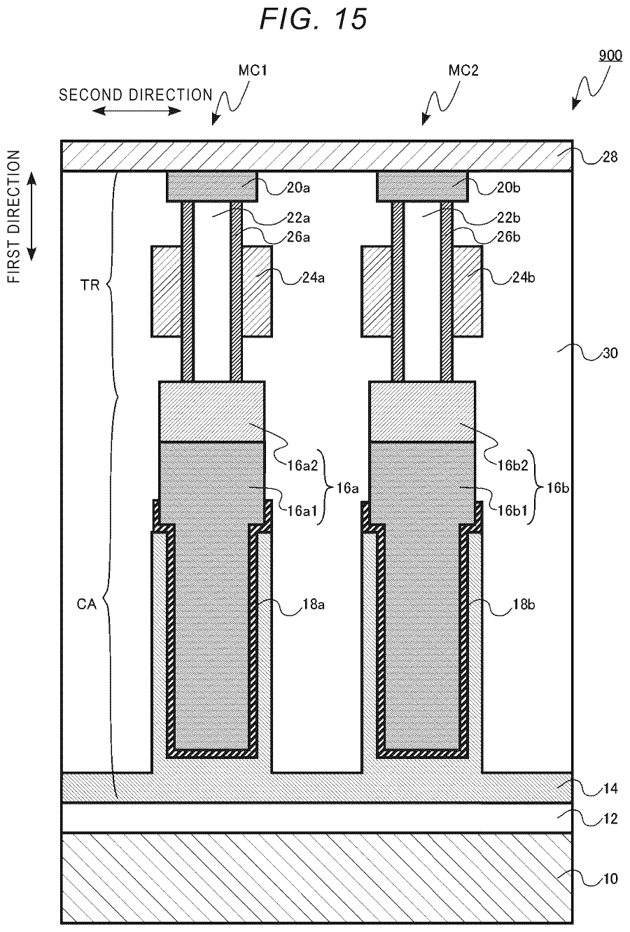

Next, a second opening 65 that penetrates the fifth silicon oxide film 64, the tungsten film 63, and the fourth silicon oxide film 62 and reaches the indium tin oxide film 60 is formed (FIG. 14). The second opening 65 is formed, for example, by a lithography method and an RIE method.

Next, in the second opening 65, the gate insulating film 26 of silicon nitride and the oxide semiconductor layer 22 of indium gallium zinc oxide are formed. Next, the source/drain electrode 20 of indium tin oxide is formed on the oxide semiconductor layer 22. Then, the bit line 28 of tungsten is formed on the source/drain electrode 20.

The semiconductor memory 100 shown in FIGS. 2, 3, 4, 5, and 6 is manufactured by the above-described manufacturing method.

Next, the operations and effects of the semiconductor memory device according to the first embodiment will be described.

When an oxide semiconductor transistor is applied to a switching transistor of a memory cell of a DRAM, an oxide semiconductor layer of the oxide semiconductor transistor is electrically connected to a storage node electrode of a capacitor. From the viewpoint of improving the characteristics of the memory cell of the DRAM, it is desirable to reduce connection resistance between the oxide semiconductor layer and the storage node electrode. By reducing the connection resistance between the oxide semiconductor layer and the storage node electrode, for example, the operating speed of the memory cell is improved.

FIG. 15 is a schematic cross-sectional view of a semiconductor memory device according to a comparative embodiment. A semiconductor memory 900 according to the comparative embodiment is a DRAM. The semiconductor memory 900 uses an oxide semiconductor transistor as a switching transistor of a memory cell of a DRAM. FIG. 15 is a diagram corresponding to FIG. 2 in the first embodiment.

The semiconductor memory 900 according to the comparative embodiment differs from the semiconductor memory 100 according to the first embodiment in that the width of the upper portion of the storage node electrode 16 in the second direction is constant. The semiconductor memory 900 differs from the semiconductor memory 100 of the first embodiment in that the upper portion of the storage node electrode 16 is not barrel-shaped but rectangular in a cross section parallel to the first direction. The semiconductor memory 900 also differs from the semiconductor memory 100 according to the first embodiment in that the first oxide conductor region 16a2 does not cover the side surface of the first metal region 16al. The semiconductor memory 900 also differs from the semiconductor memory 100 according to the first embodiment in that the second oxide conductor region 16b2 does not cover the side surface of the second metal region 16bl.

In the semiconductor memory 900 according to the comparative embodiment, the width of the upper portion of the storage node electrode 16 in the second direction is constant. For this reason, the electrical resistance of the upper portion of the storage node electrode 16 becomes large, and there is a concern that the connection resistance between the oxide semiconductor layer 22 and the storage node electrode 16 becomes large.

In the semiconductor memory 100 according to the first embodiment, the width of the upper portion of the storage node electrode 16 in the second direction is partially expanded. For this reason, the electrical resistance of the upper portion of the storage node electrode 16 is reduced, and the connection resistance between the oxide semiconductor layer 22 and the storage node electrode 16 is reduced.

In the semiconductor memory 900 according to the comparative embodiment, the first oxide conductor region 16a2 and the first metal region 16a1 of the first memory cell MC1 are in contact with each other only on the upper surface of the first metal region 16al. Thus, there is a concern that the interface resistance between the first oxide conductor region 16a2 and the first metal region 16a1 may become large. Thus, there is a concern that the connection resistance between the first oxide semiconductor layer 22a and the first storage node electrode 16a may become large. For the same reason, there is a concern that the connection resistance between the second oxide semiconductor layer 22b of the second memory cell MC2 and the second storage node electrode 16b may become large.

In the semiconductor memory 100 according to the first embodiment, the first oxide conductor region 16a2 and the first metal region 16a1 of the first memory cell MC1 are in contact with each other on the upper surface and side surface of the first metal region 16al. For this reason, the interface resistance between the first oxide conductor region 16a2 and the first metal region 16a1 is reduced, and the connection resistance between the first oxide semiconductor layer 22a and the first storage node electrode 16a is reduced. For the same reason, the connection resistance between the second oxide semiconductor layer 22b and the second storage node electrode 16b of the second memory cell MC2 is reduced.

From the viewpoint of further reducing the interface resistance between the first oxide conductor region 16a2 and the first metal region 16al, as shown in FIG. 6, it is preferable that the first oxide conductor region 16a2 surrounds at least a portion of the first metal region 16a1 in a cross section perpendicular to the first direction. For the same reason, it is preferable that the second oxide conductor region 16b2 surrounds at least a portion of the second metal region 16b1 in a cross section perpendicular to the first direction.

In the semiconductor memory 900 according to the comparative embodiment, the width of the upper portion of the storage node electrode 16 in the second direction is constant. For this reason, when an opening for forming the oxide semiconductor layer 22 is provided on the storage node electrode 16, an alignment margin between the opening and the upper surface of the storage node electrode 16 becomes small. Thus, there is a concern that it may become difficult to manufacture the semiconductor memory 900.

In the semiconductor memory 100 according to the first embodiment, the width of the upper portion of the storage node electrode 16 in the second direction is partially expanded. Thus, when an opening for forming the oxide semiconductor layer 22 is provided on the storage node electrode 16, an alignment margin between the opening and the upper portion of the storage node electrode 16 becomes large. Thus, it becomes easy to manufacture the semiconductor memory 100.

In the semiconductor memory 100 according to the first embodiment, the corners of the upper surface of the upper portion of the storage node electrode 16 are formed into a forward tapered shape. Thus, when an insulating film is formed on the storage node electrode 16, a burying property is improved. For example, the burying property of the insulating film in the portion between the first oxide conductor region 16a2 and the second oxide conductor region 16b2 is improved. Thus, for example, the manufacturing yield of the semiconductor memory 100 is improved.

The first width W1 of the first portion 16ax of the first storage node electrode 16a is preferably 0.5 times or more and 0.9 times or less the second width W2, and more preferably 0.6 times or more and 0.8 times or less.

By exceeding the lower limit, the width of the upper portion of the first storage node electrode 16a in the second direction is increased, and the electrical resistance of the storage node electrode 16 is reduced. Furthermore, by exceeding the lower limit, the width of the upper portion of the first storage node electrode 16a in the second direction is increased, and when an opening for forming the oxide semiconductor layer 22 is provided on the storage node electrode 16, an alignment margin between the opening and the upper portion of the storage node electrode 16 is increased.

Furthermore, by falling below the upper limit, a distance between the first storage node electrode 16a and the second storage node electrode 16b can be secured, and an electrical short between the first storage node electrode 16a and the second storage node electrode 16b can be curbed.

For the same reasons as above, the fourth width W4 of the fourth portion 16bx of the second storage node electrode 16b is preferably 0.5 times or more and 0.9 times or less the fifth width W5, and more preferably 0.6 times or more and 0.8 times or less.

The third width W3 of the first storage node electrode 16a is preferably 0.7 times or more and 0.95 times or less the second width W2, and more preferably 0.8 times or more and 0.9 times or less.

By exceeding the lower limit, the width of the upper surface of the first storage node electrode 16a in the second direction is increased, and the electrical resistance of the storage node electrode 16 is reduced. Furthermore, by exceeding the lower limit, the width of the upper surface of the first storage node electrode 16a in the second direction is increased, and when an opening for forming the oxide semiconductor layer 22 is provided on the storage node electrode 16, an alignment margin between the opening and the upper surface of the storage node electrode 16 is increased.

Furthermore, by falling below the upper limit, a forward taper angle of the corner of the upper surface of the upper portion of the storage node electrode 16 becomes larger, and a burying property is further improved when forming an insulating film on the first storage node electrode 16a.

For the same reason as above, the sixth width W6 of the second storage node electrode 16b is preferably 0.7 times or more and 0.95 times or less the fifth width W5, and more preferably 0.8 times or more and 0.9 times or less.

From the viewpoint of reducing the electrical resistance of the first storage node electrode 16a, it is preferable that the third width W3 of the first storage node electrode 16a be larger than the first width W1. From the viewpoint of reducing the electrical resistance of the second storage node electrode 16b, it is preferable that the sixth width W6 of the second storage node electrode 16b be larger than the fourth width W4.

From the viewpoint of reducing the electrical resistance of the storage node electrode 16, it is preferable that the shortest distance (d in FIG. 5) between the first storage node electrode 16a and the second storage node electrode 16b in the second direction is smaller than the first width W1 of the first storage node electrode 16a and the fourth width W4 of the second storage node electrode 16b.

According to the semiconductor memory 100 according to the first embodiment, the connection resistance between the oxide semiconductor layer 22 and the storage node electrode 16 can be reduced.

### First Modification Example

A semiconductor memory device according to a first modification example of the first embodiment differs from the semiconductor memory device according to the first embodiment in that a second electrode further includes a third region of a semiconductor surrounded by a first region. In the following, some of the contents that are repeated in the first embodiment may be omitted.

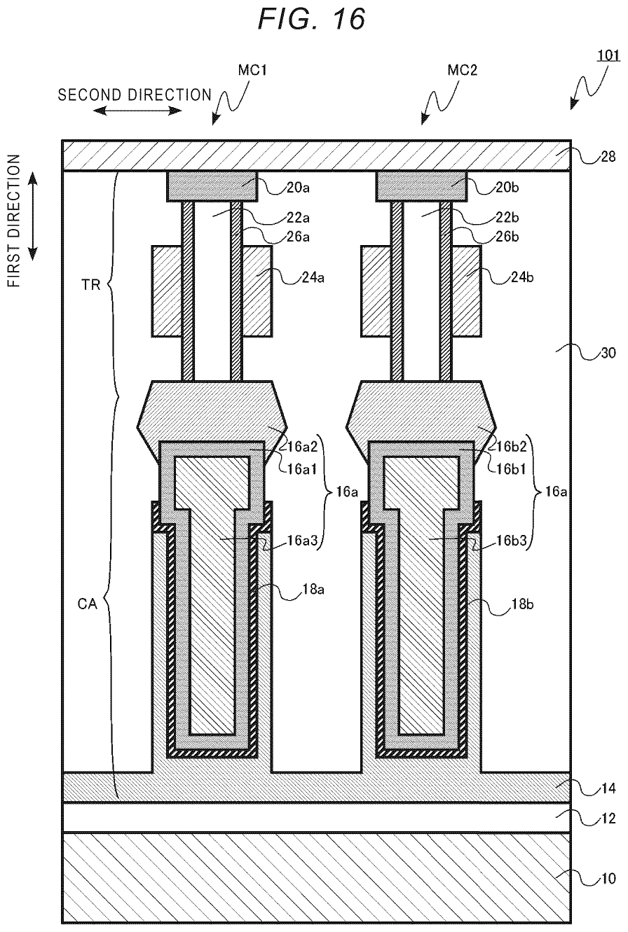

FIG. 16 is a schematic cross-sectional view of the semiconductor memory device according to the first modification example of the first embodiment. The semiconductor memory device according to the first modification example is a semiconductor memory 101. FIG. 16 is a diagram corresponding to FIG. 2 in the first embodiment.

The first storage node electrode 16a further includes a first semiconductor region 16a3. The first semiconductor region 16a3 is an example of a third region.

The first semiconductor region 16a3 is surrounded by the first metal region 16al. The first semiconductor region 16a3 includes a semiconductor. The first semiconductor region 16a3 is made of, for example, polycrystalline silicon germanium containing conductive impurities. The first semiconductor region 16a3 is made of, for example, polycrystalline silicon containing conductive impurities.

The second storage node electrode 16b further includes a second semiconductor region 16b3.

The second semiconductor region 16b3 is surrounded by the second metal region 16b1. The second semiconductor region 16b3 includes a semiconductor. The second semiconductor region 16b3 is made of, for example, polycrystalline silicon germanium containing conductive impurities. The second semiconductor region 16b3 is made of, for example, polycrystalline silicon containing conductive impurities.

When the semiconductor memory 101 is manufactured, for example, the first metal region 16a1 in contact with the bottom surface and side surface of the first semiconductor region 16a3 and the first metal region 16a1 in contact with the upper surface of the first semiconductor region 16a3 are formed as separate films. Similarly, the second metal region 16b1 in contact with the bottom surface and side surface of the second semiconductor region 16b3 and the second metal region 16b1 in contact with the upper surface of the second semiconductor region 16b3 are formed as separate films.

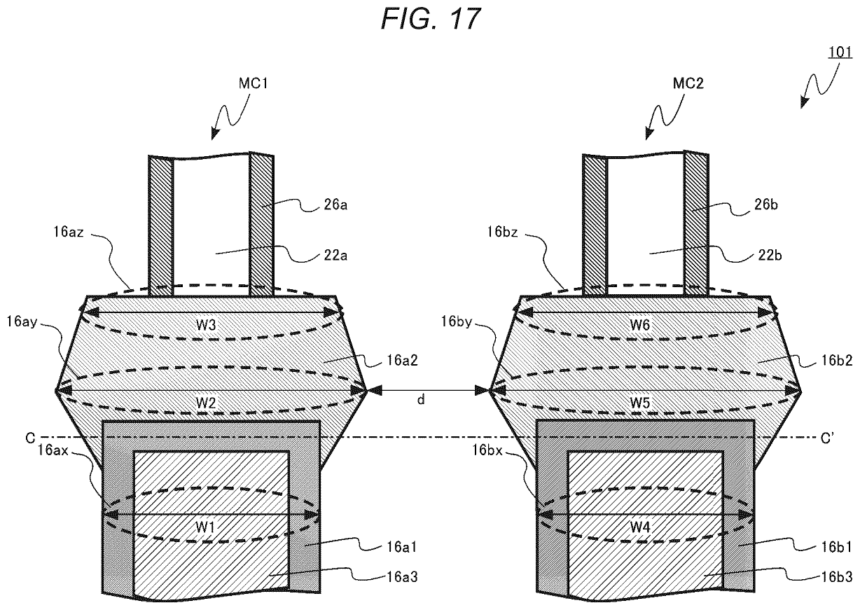

FIG. 17 is a schematic enlarged cross-sectional view of the semiconductor memory device according to the first modification example of the first embodiment. FIG. 17 is a schematic enlarged cross-sectional view of a portion of FIG. 16. FIG. 17 shows a portion of the storage node electrode 16, a portion of the oxide semiconductor layer 22, and a portion of the gate insulating film 26 of the first memory cell MC1 and the second memory cell MC2. FIG. 17 is a diagram corresponding to FIG. 5 in the first embodiment.

The first storage node electrode 16a includes a first portion 16ax, a second portion 16ay, and a third portion 16az. The second portion 16ay is provided between the first oxide semiconductor layer 22a and the first portion 16ax. The third portion 16az is provided between the first oxide semiconductor layer 22a and the second portion 16ay.

The third portion 16az, which is the uppermost portion of the first storage node electrode 16a, contacts (e.g., in in contact with), for example, the first oxide semiconductor layer 22a.

A first width (W1 in FIG. 17) of the first portion 16ax in the second direction is smaller than a second width (W2 in FIG. 17) of the second portion 16ay in the second direction. In addition, a third width (W3 in FIG. 17) of the third portion 16az in the second direction is smaller than the second width W2.

The first portion 16ax is located, for example, across the first metal region 16a1 and the first semiconductor region 16a3. The second portion 16ay is located, for example, in the first oxide conductor region 16a2. The third portion 16az is located, for example, in the first oxide conductor region 16a2.

The second storage node electrode 16b includes a fourth portion 16bx, a fifth portion 16by, and a sixth portion 16bz. The fifth portion 16by is provided between the second oxide semiconductor layer 22b and the fourth portion 16bx. The sixth portion 16bz is provided between the second oxide semiconductor layer 22b and the fifth portion 16by.

The sixth portion 16bz, which is the uppermost portion of the second storage node electrode 16b, contacts (e.g., in in contact with), for example, the second oxide semiconductor layer 22b.

A fourth width (W4 in FIG. 17) of the fourth portion 16bx in the second direction is smaller than a fifth width (W5 in FIG. 17) of the fifth portion 16by in the second direction. In addition, a sixth width (W6 in FIG. 17) of the sixth portion 16bz in the second direction is smaller than the fifth width W5.

The fourth portion 16bx is located, for example, across the second metal region 16b1 and the second semiconductor region 16b3. The fifth portion 16by is located, for example, in the second oxide conductor region 16b2. The sixth portion 16bz is located, for example, in the second oxide conductor region 16b2.

According to the semiconductor memory 101 according to the first modification example of the first embodiment, the connection resistance between the oxide semiconductor layer 22 and the storage node electrode 16 can be reduced, similar to the semiconductor memory 100 according to the first embodiment.

### Second Modification Example

A semiconductor memory device according to a second modification example of the first embodiment further includes a first insulating layer provided between a second electrode and a first gate electrode and in contact with the second electrode, and differs from the semiconductor memory device according to the first embodiment in that the first insulating layer surrounds a first oxide semiconductor layer in a cross section perpendicular to the first direction. In the following, some of the contents that are repeated in the first embodiment may be omitted.

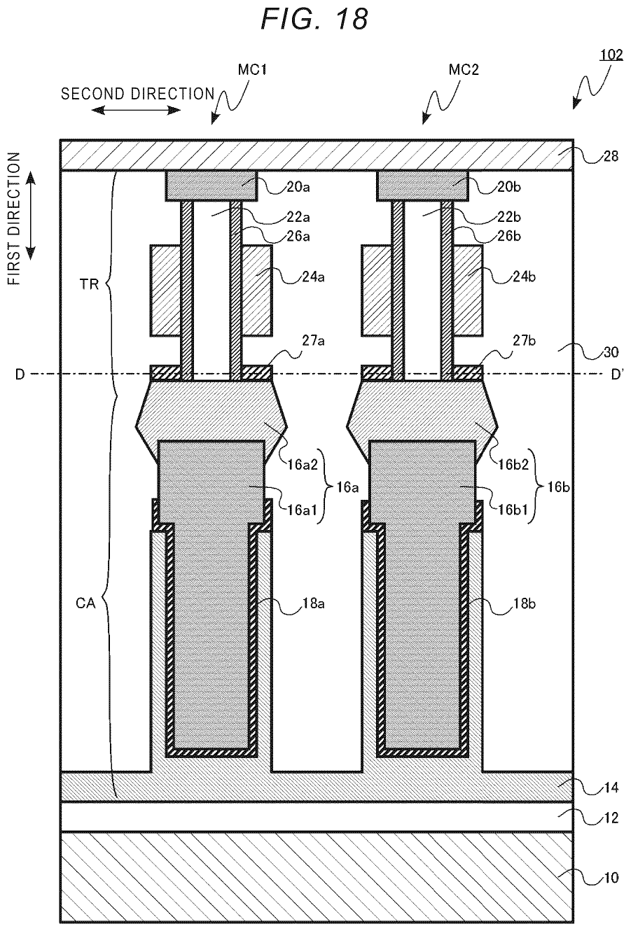

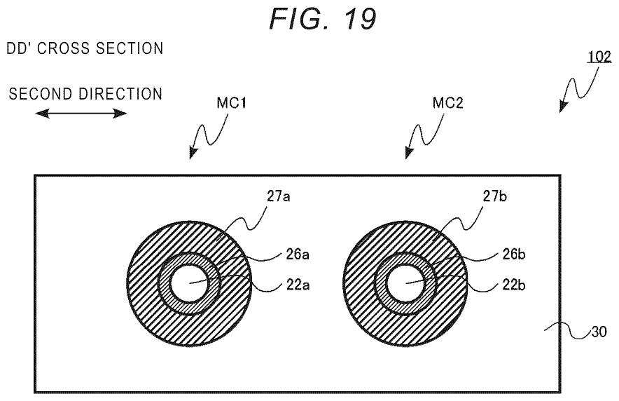

FIG. 18 is a schematic cross-sectional view of the semiconductor memory device according to the second modification example of the first embodiment. The semiconductor memory device according to the second modification example is a semiconductor memory 102. FIG. 18 is a diagram corresponding to FIG. 2 in the first embodiment.

The semiconductor memory 102 includes a first upper surface insulating layer 27a and a second upper surface insulating layer 27b. The first upper surface insulating layer 27a is an example of a first insulating layer.

The first upper surface insulating layer 27a is provided between the first storage node electrode 16a and the first gate electrode 24a. The first upper surface insulating layer 27a is provided on the first storage node electrode 16a. The first upper surface insulating layer 27a contacts (e.g., in in contact with) the first storage node electrode 16a.

The second upper surface insulating layer 27b is provided between the second storage node electrode 16b and the second gate electrode 24b. The second upper surface insulating layer 27b is provided on the second storage node electrode 16b. The second upper surface insulating layer 27b contacts (e.g., in in contact with) the second storage node electrode 16b.

FIG. 19 is a schematic cross-sectional view of the semiconductor memory device according to the second modification example of the first embodiment. FIG. 19 is a cross-sectional view taken along line DD′ in FIG. 18.

As shown in FIG. 19, the first upper surface insulating layer 27a surrounds the first oxide semiconductor layer 22a in the DD′ cross section perpendicular to the first direction. The second upper surface insulating layer 27b surrounds the second oxide semiconductor layer 22b in the DD′ cross section perpendicular to the first direction.

The first upper surface insulating layer 27a and the second upper surface insulating layer 27b are insulators. The chemical compositions of the first upper surface insulating layer 27a and the second upper surface insulating layer 27b are different from the chemical composition of the interlayer insulating layer 30. The first upper surface insulating layer 27a and the second upper surface insulating layer 27b contain, for example, silicon nitride or aluminum oxide.

The first upper surface insulating layer 27a and the second upper surface insulating layer 27b function as, for example, a hard mask on the storage node electrode 16 when manufacturing the semiconductor memory 102. In addition, for example, the first upper surface insulating layer 27a and the second upper surface insulating layer 27b function as an etching stopper film when forming an opening for burying the oxide semiconductor layer 22 on the storage node electrode 16.

According to the semiconductor memory 102 according to the second modification example of the first embodiment, the connection resistance between the oxide semiconductor layer 22 and the storage node electrode 16 can be reduced, similar to the semiconductor memory 100 according to the first embodiment.

As described above, according to the first embodiment and the modification examples, it is possible to implement a semiconductor memory device including an oxide semiconductor transistor and having low connection resistance between an oxide semiconductor layer of the oxide semiconductor transistor and a storage node electrode.

### Second Embodiment

A semiconductor memory device according to a second embodiment differs from the semiconductor memory device according to the first embodiment in that a second electrode surrounds a first electrode in a cross section perpendicular to the first direction. In the following, some of the contents that are repeated in the first embodiment may be omitted.

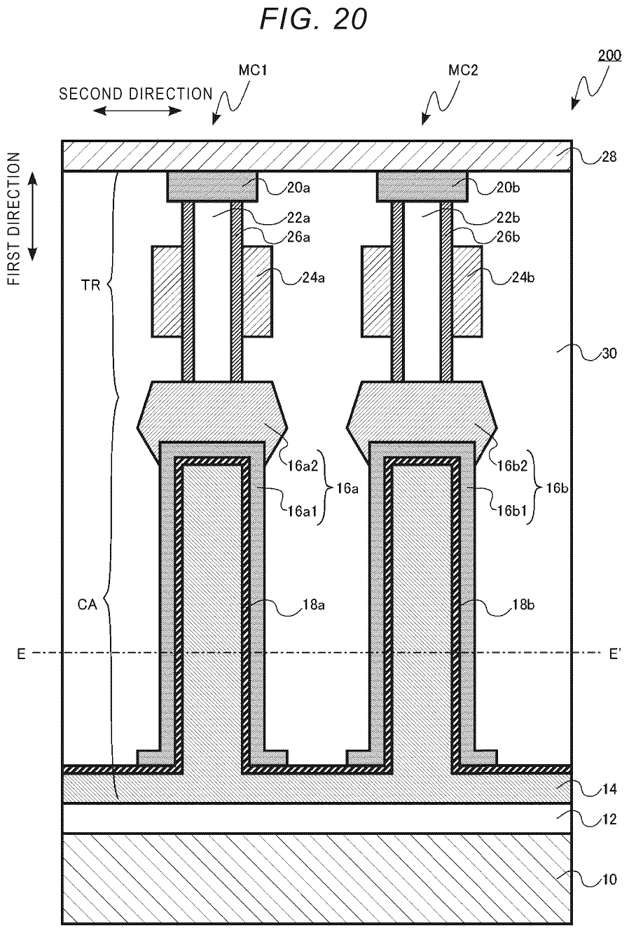

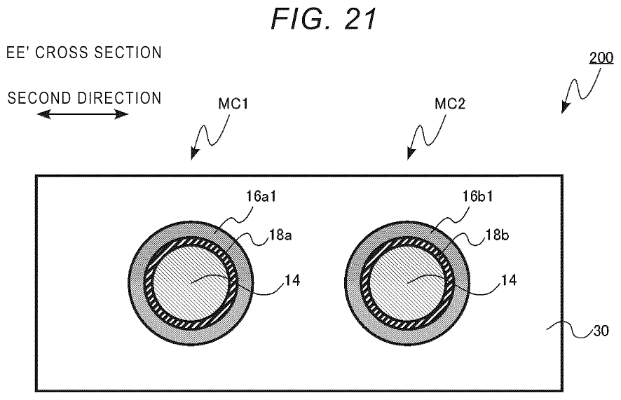

FIGS. 20 and 21 are schematic cross-sectional views of the semiconductor memory device according to the second embodiment.

FIG. 21 is a cross-sectional view taken along line EE′ in FIG. 20.

A semiconductor memory 200 according to the second embodiment includes a substrate 10, a substrate insulating layer 12, a plate electrode 14, a first storage node electrode 16a, a second storage node electrode 16b, a first capacitor insulating film 18a, a second capacitor insulating film 18b, a first source/drain electrode 20a, a second source/drain electrode 20b, a first oxide semiconductor layer 22a, a second oxide semiconductor layer 22b, a first gate electrode 24a, a second gate electrode 24b, a first gate insulating film 26a, a second gate insulating film 26b, a bit line 28, and an interlayer insulating layer 30.

The first storage node electrode 16a includes a first metal region 16a1 and a first oxide conductor region 16a2. The second storage node electrode 16b includes a second metal region 16b1 and a second oxide conductor region 16b2.

The plate electrode 14 is an example of a first electrode. The first storage node electrode 16a is an example of a second electrode. The second storage node electrode 16b is an example of a fourth electrode. The first source/drain electrode 20a is an example of a third electrode. The second source/drain electrode 20 is an example of a fifth electrode.

The first metal region 16a1 is an example of a first region. The first oxide conductor region 16a2 is an example of a second region.

Hereinafter, the first storage node electrode 16a and the second storage node electrode 16b may be collectively referred to as a storage node electrode 16. In addition, the first capacitor insulating film 18a and the second capacitor insulating film 18b may be collectively referred to as a capacitor insulating film 18. In addition, the first source/drain electrode 20a and the second source/drain electrode 20b may be collectively referred to as a source/drain electrode 20. In addition, the first oxide semiconductor layer 22a and the second oxide semiconductor layer 22b may be collectively referred to as an oxide semiconductor layer 22. In addition, the first gate electrode 24a and the second gate electrode 24b may be collectively referred to as a gate electrode 24. In addition, the first gate insulating film 26a and the second gate insulating film 26b may be collectively referred to as a gate insulating film 26.

The plate electrode 14 is provided inside the storage node electrode 16. As shown in FIG. 21, in the EE′ cross section perpendicular to the first direction, the storage node electrode 16 surrounds the plate electrode 14. In the EE′ cross section, the storage node electrode 16 surrounds the capacitor insulating film 18. In the EE′ cross section, the capacitor insulating film 18 surrounds the plate electrode 14.

As shown in FIG. 21, in the EE′ cross section perpendicular to the first direction, the first storage node electrode 16a surrounds the plate electrode 14. In the EE′ cross section, the first metal region 16a1 surrounds the plate electrode 14. In the EE′ cross section, the first storage node electrode 16a surrounds the first capacitor insulating film 18a. In the EE′ cross section, the first capacitor insulating film 18a surrounds the plate electrode 14.

As shown in FIG. 21, in the EE′ cross section perpendicular to the first direction, the second storage node electrode 16b surrounds the plate electrode 14. In the EE′ cross section, the second metal region 16b1 surrounds the plate electrode 14. In the EE′ cross section, the second storage node electrode 16b surrounds the second capacitor insulating film 18b. In the EE′ cross section, the second capacitor insulating film 18b surrounds the plate electrode 14.

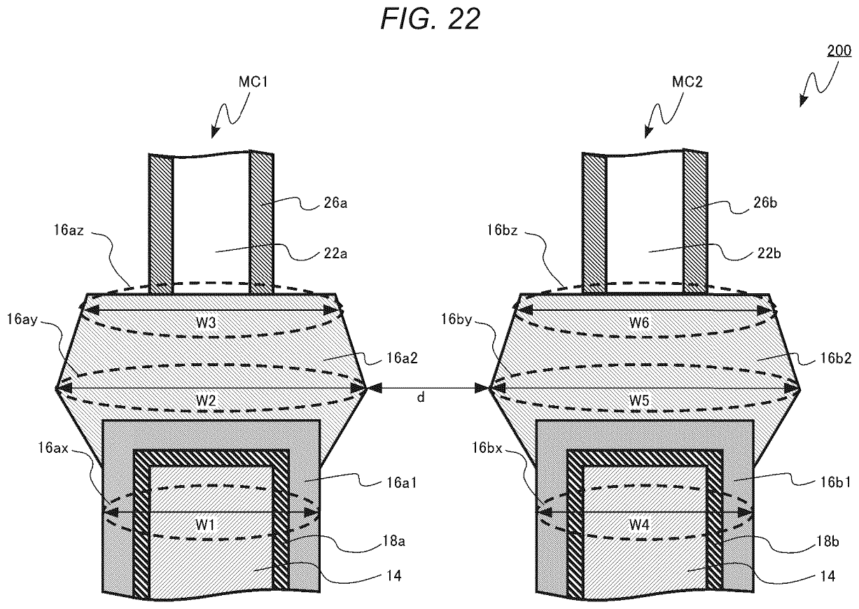

FIG. 22 is a schematic enlarged cross-sectional view of the semiconductor memory device according to the second embodiment. FIG. 22 is a schematic enlarged cross-sectional view of a portion of FIG. 20. FIG. 22 shows a portion of the storage node electrode 16, a portion of the oxide semiconductor layer 22, and a portion of the gate insulating film 26 of a first memory cell MC1 and a second memory cell MC2. FIG. 22 is a diagram corresponding to FIG. 5 in the first embodiment.

The first storage node electrode 16a includes a first portion 16ax, a second portion 16ay, and a third portion 16az. The second portion 16ay is provided between the first oxide semiconductor layer 22a and the first portion 16ax. The third portion 16az is provided between the first oxide semiconductor layer 22a and the second portion 16ay.

The third portion 16az, which is the uppermost portion of the first storage node electrode 16a, contacts (e.g., in in contact with), for example, the first oxide semiconductor layer 22a.

A first width (W1 in FIG. 22) of the first portion 16ax in the second direction is smaller than a second width (W2 in FIG. 22) of the second portion 16ay in the second direction. In addition, a third width (W3 in FIG. 22) of the third portion 16az in the second direction is smaller than the second width W2.

The first portion 16ax is located, for example, across the first metal region 16a1 on the right and left with the plate electrode 14 interposed therebetween. The second portion 16ay is located, for example, in the first oxide conductor region 16a2. The third portion 16az is located, for example, in the first oxide conductor region 16a2.

The second storage node electrode 16b includes a fourth portion 16bx, a fifth portion 16by, and a sixth portion 16bz. The fifth portion 16by is provided between the second oxide semiconductor layer 22b and the fourth portion 16bx. The sixth portion 16bz is provided between the second oxide semiconductor layer 22b and the fifth portion 16by.

The sixth portion 16bz, which is the uppermost portion of the second storage node electrode 16b, contacts (e.g., in in contact with), for example, the second oxide semiconductor layer 22b.

A fourth width (W4 in FIG. 22) of the fourth portion 16bx in the second direction is smaller than a fifth width (W5 in FIG. 22) of the fifth portion 16by in the second direction. In addition, a sixth width (W6 in FIG. 22) of the sixth portion 16bz in the second direction is smaller than the fifth width W5.

The fourth portion 16bx is located, for example, across the second metal region 16b1 on the right and left with the plate electrode 14 interposed therebetween. The fifth portion 16by is located, for example, in the second oxide conductor region 16b2. The sixth portion 16bz is located, for example, in the second oxide conductor region 16b2.

Next, an example of a manufacturing method for the semiconductor memory device according to the second embodiment will be described.

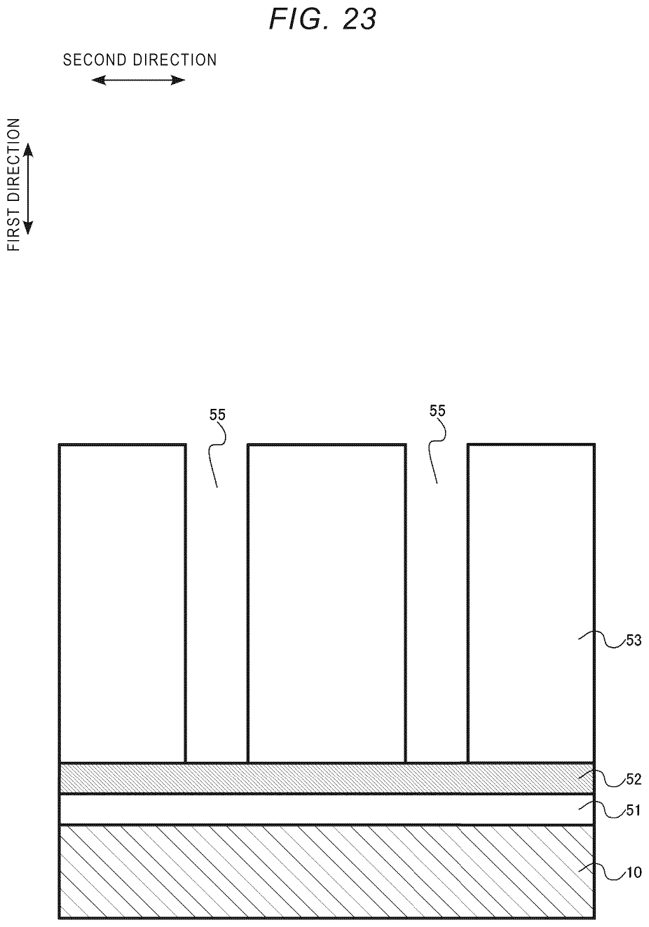

FIGS. 23, 24, 25, 26, 27, 28, and 29 are schematic cross-sectional views showing an example of a manufacturing method for the semiconductor memory device according to the second embodiment. FIGS. 23 to 29 shows cross sections corresponding to FIG. 20. FIGS. 23 to 29 are diagrams showing an example of a manufacturing method for the semiconductor memory 200.

Hereinafter, description will be given of an example of a case where the substrate insulating layer 12 is made of silicon oxide, the plate electrode 14 is made of titanium nitride, the metal region of the storage node electrode 16 is made of titanium nitride, the oxide conductor region of the storage node electrode 16 is made of indium tin oxide, the capacitor insulating film 18 is made of zirconium oxide, the source/drain electrode 20 is made of indium tin oxide, the oxide semiconductor layer 22 is made of indium gallium zinc oxide, the gate electrode 24 is made of tungsten, the gate insulating film 26 is made of silicon nitride, and the interlayer insulating layer 30 is made of silicon oxide.

First, a first silicon oxide film 51, a first titanium nitride film 52, and a second silicon oxide film 53 are formed on the substrate 10. The first silicon oxide film 51, the first titanium nitride film 52, and the second silicon oxide film 53 are formed, for example, by a CVD method.

The first silicon oxide film 51 eventually becomes the substrate insulating layer 12. The first titanium nitride film 52 eventually becomes a portion of the plate electrode 14. The second silicon oxide film 53 eventually becomes a portion of the interlayer insulating layer 30.

Next, a first opening 55 that penetrates the second silicon oxide film 53 and reaches the first titanium nitride film 52 is formed (FIG. 23). The first opening 55 is formed, for example, using a lithography method and an RIE method.

Next, the first opening 55 is filled with a second titanium nitride film 56. The second titanium nitride film 56 is formed, for example, using a CVD method.

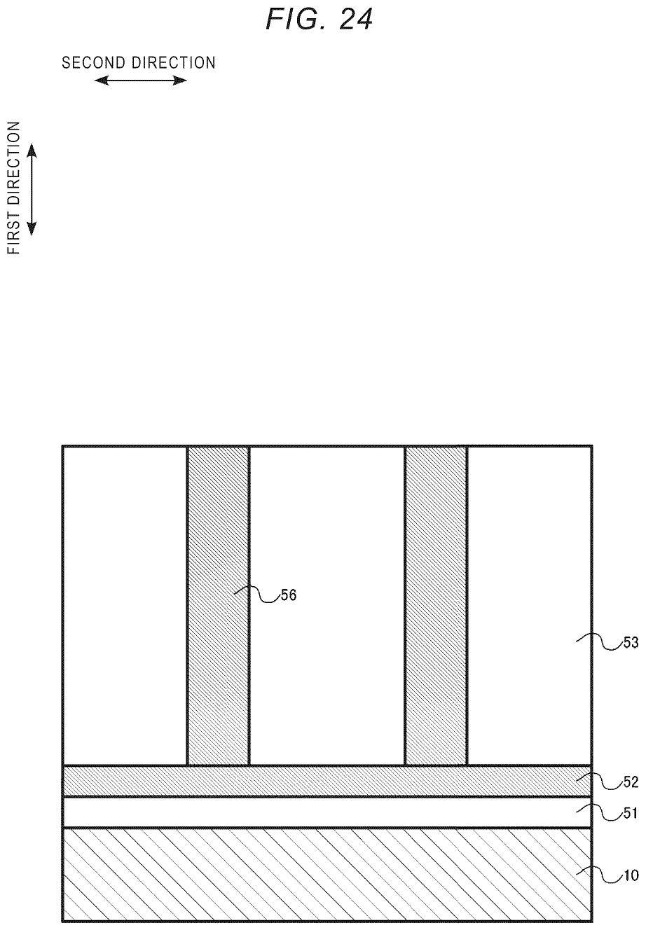

Next, the second titanium nitride film 56 on the surface of the second silicon oxide film 53 is removed (FIG. 24). The second titanium nitride film 56 is removed, for example, by a CMP method. The second titanium nitride film 56 eventually becomes a portion of the plate electrode 14.

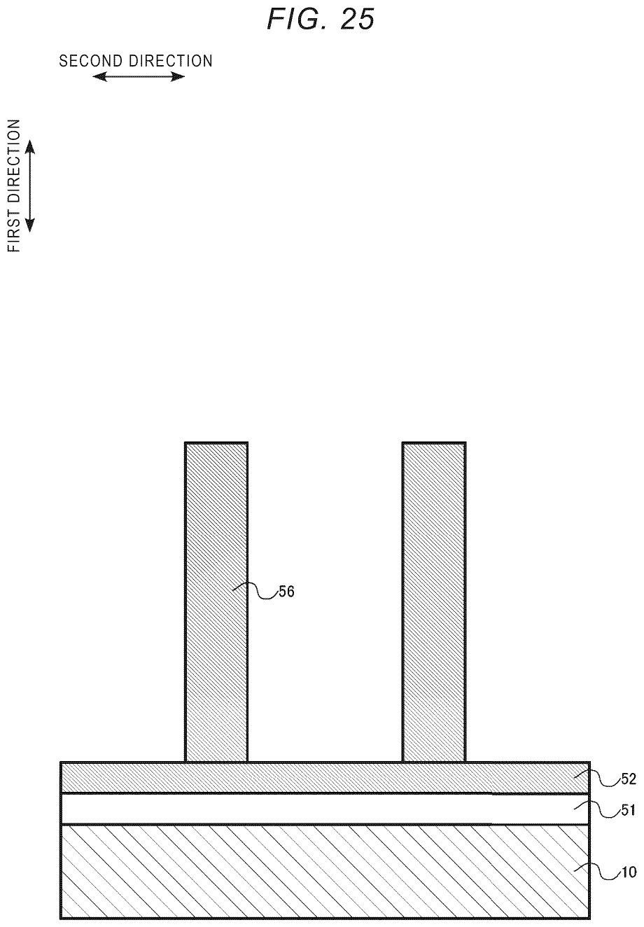

Next, the second silicon oxide film 53 is removed (FIG. 25). The second silicon oxide film 53 is removed, for example, using a wet etching method. A pillar formed with the second titanium nitride film 56 is formed.

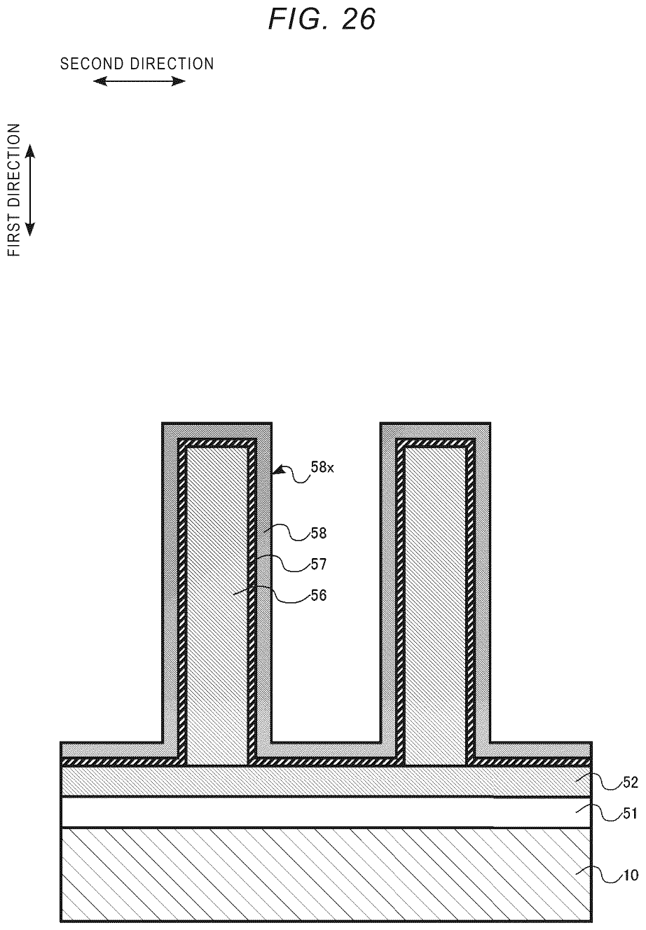

Next, a zirconium oxide film 57 and a third titanium nitride film 58 are formed on the pillar formed with the second titanium nitride film 56 (FIG. 26). The zirconium oxide film 57 and the third titanium nitride film 58 are formed, for example, using an ALD method.

The zirconium oxide film 57 eventually becomes the capacitor insulating film 18. The third titanium nitride film 58 eventually becomes a portion of the storage node electrode 16.

The zirconium oxide film 57 and the third titanium nitride film 58 are formed on the pillar formed with the second titanium nitride film 56, and thus a titanium nitride pillar 58x protruding from a periphery is formed.

The pillar 58x has a stacked structure of the second titanium nitride film 56, the zirconium oxide film 57, and the third titanium nitride film 58. The upper surface and side surface of the pillar 58x are made of titanium nitride.

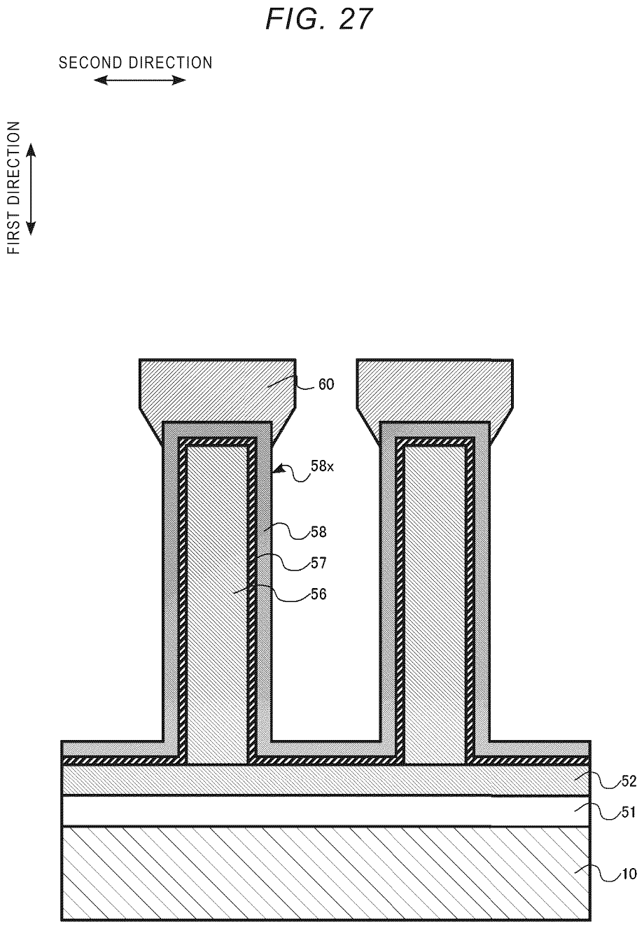

Next, an indium tin oxide film 60 is formed on the upper surface of the pillar 58x (FIG. 27). The indium tin oxide film 60 is formed under a condition that a growth rate in the upward direction becomes higher than a growth rate in the lateral direction. The indium tin oxide film 60 is also formed under a condition that a step coverage is poor.

The width of the indium tin oxide film 60 formed on the upper surface of the pillar 58x in the second direction is larger than the width of the pillar 58x in the second direction. In addition, the indium tin oxide films 60 formed on the upper surfaces of two pillars 58x adjacent to each other in the second direction are formed not to come into contact with each other.

The indium tin oxide film 60 is formed under conditions that, for example, [111] directions of a plurality of crystals contained in the indium tin oxide film 60 are oriented in a direction perpendicular to the upper surface of the pillar 58x of the third titanium nitride film 58. The indium tin oxide film 60 is formed such that, for example, the [111] directions of a plurality of crystals contained in the indium tin oxide film 60 are oriented in the first direction. By forming the indium tin oxide film 60 such that the [111] directions of the plurality of crystals contained in the indium tin oxide film 60 are oriented in the first direction, a growth rate of the indium tin oxide film 60 in the upward direction becomes higher than a growth rate in the lateral direction.

For example, the indium tin oxide film 60 is formed to cover a portion of the side surface of the pillar 58x. The indium tin oxide film 60 is formed under a condition that a growth rate in the upward direction is high, and thus the indium tin oxide films 60 on two adjacent pillars 58x are prevented from coming into contact with each other. In addition, the indium tin oxide film 60 is formed under a condition that a step coverage is poor, and thus the indium tin oxide film 60 is hardly formed on the upper surface of the third titanium nitride film 58 between the two adjacent pillars 58x.

The indium tin oxide film 60 is formed, for example, by a PVD method, which has poor step coverage. The indium tin oxide film 60 is formed, for example, by a sputtering method, which has poor step coverage.

Next, the third titanium nitride film 58 between the two adjacent pillars 58x is removed using the indium tin oxide film 60 as a mask. The third titanium nitride film 58 is removed, for example, by an RIE method. Before the etching performed using the RIE method, for example, a hard mask may be formed on the indium tin oxide film 60.

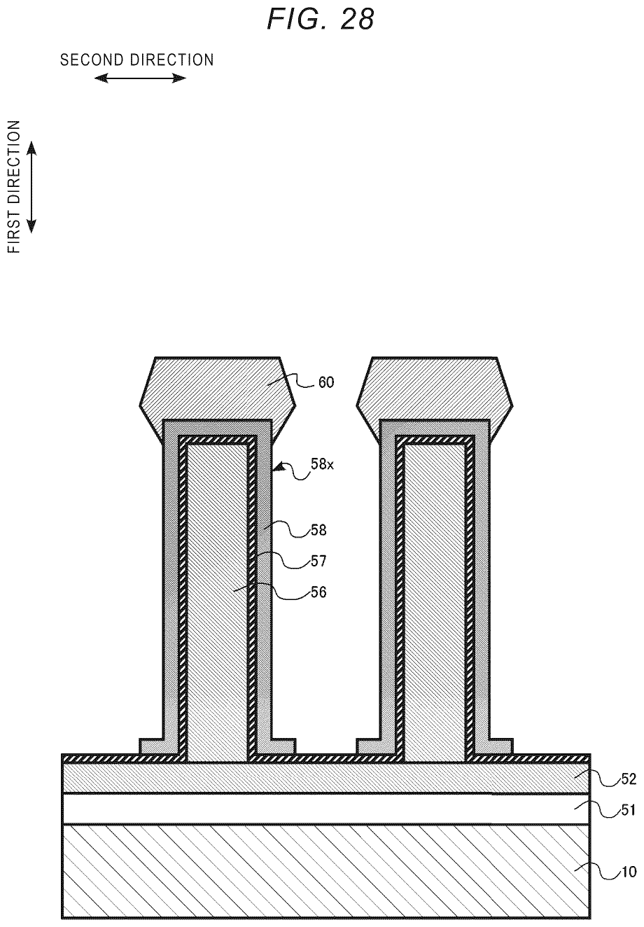

Next, the corners of the upper surface of the indium tin oxide film 60 are removed (FIG. 28). The corners of the upper surface of the indium tin oxide film 60 are formed into a forward tapered shape. The corners of the upper surface of the indium tin oxide film 60 may be removed before removing the third titanium nitride film 58 between two adjacent pillars 58x.

For example, the corners of the upper surface of the indium tin oxide film 60 are removed by an RIE method for removing the third titanium nitride film 58. In addition, for example, the corners of the upper surface of the indium tin oxide film 60 are removed by a wet etching method.

For example, when the indium tin oxide film 60 is formed on the upper surface of the third titanium nitride film 58 between two pillars 58x, it is possible to remove the indium tin oxide film 60 by etching for removing the corners of the upper surface of the indium tin oxide film 60.

Next, a third silicon oxide film 61 is formed on the indium tin oxide film 60. The third silicon oxide film 61 is formed, for example, by a CVD method. The corners of the upper surface of the indium tin oxide film 60 are formed into a forward tapered shape, which improves a burying property of the third silicon oxide film 61 between the two adjacent pillars 58x. The third silicon oxide film 61 eventually becomes a portion of the interlayer insulating layer 30.

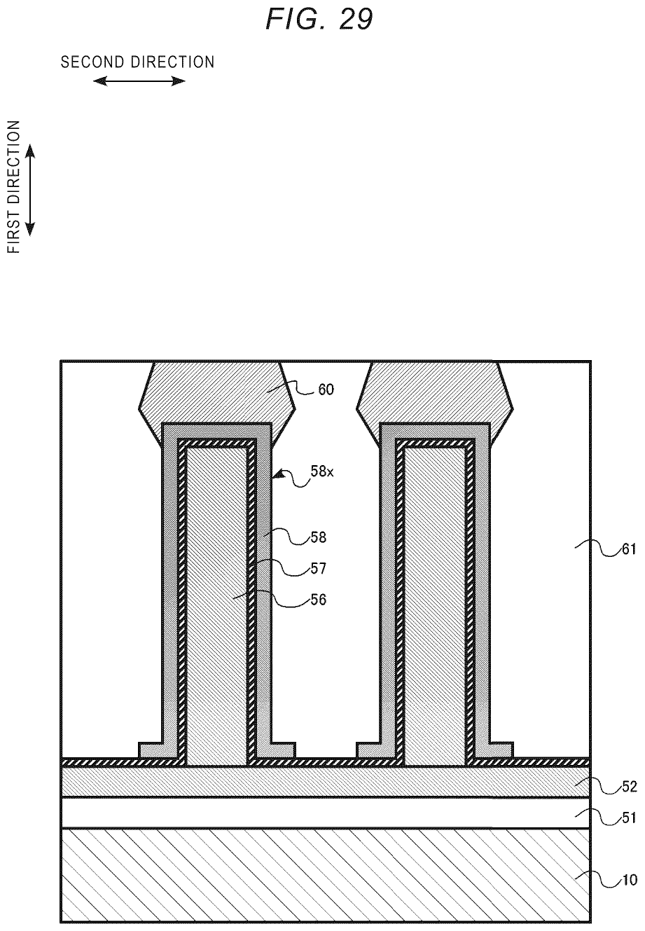

Next, the third silicon oxide film 61 on the indium tin oxide film 60 is removed (FIG. 29). The third silicon oxide film 61 is removed, for example, by a CMP method.

Then, a transistor is formed on the indium tin oxide film 60 using the same manufacturing method for the semiconductor memory 100 according to the first embodiment. The gate electrode 24 of tungsten, the gate insulating film 26 of silicon nitride, the oxide semiconductor layer 22 of indium gallium zinc oxide, the source/drain electrode 20 of indium tin oxide, and the bit line 28 of tungsten are formed on the indium tin oxide film 60.

The semiconductor memory 200 shown in FIGS. 20, 21, and 22 is manufactured by the above-described manufacturing method.

As described above, according to the second embodiment, it is possible to implement a semiconductor memory device including an oxide semiconductor transistor and having low connection resistance between an oxide semiconductor layer of the oxide semiconductor transistor and a storage node electrode, as in the first embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device, comprising:
a first capacitor comprising a first electrode, a second electrode, and a first capacitor insulating film provided between the first electrode and the second electrode; and
a first transistor comprising a first oxide semiconductor layer electrically connected to the second electrode and extending in a first direction, a first gate electrode provided next to the first oxide semiconductor layer, a first gate insulating film provided between the first gate electrode and the first oxide semiconductor layer, and a third electrode electrically connected to the first oxide semiconductor layer and provided with the first oxide semiconductor layer between the second electrode and the third electrode;
wherein the second electrode comprises a first portion, a second portion provided between the first portion and the first oxide semiconductor layer, and a third portion provided between the second portion and the first oxide semiconductor layer;
wherein a first width of the first portion in a second direction perpendicular to the first direction is smaller than a second width of the second portion in the second direction; and
wherein a third width of the third portion in the second direction is smaller than the second width.

2. The semiconductor memory device of claim 1, wherein the third portion contacts the first oxide semiconductor layer.

3. The semiconductor memory device of claim 1, further comprising a substrate, wherein the first capacitor is provided between the substrate and the first transistor.

4. The semiconductor memory device of claim 1, wherein the first width is 0.5 times or more and 0.9 times or less the second width, and the third width is 0.7 times or more and 0.95 times or less the second width.

5. The semiconductor memory device of claim 1, wherein the third width is larger than the first width.

6. The semiconductor memory device of claim 1, wherein the second electrode comprises a first region containing a metal or a metal compound, and a second region provided between the first region and the first oxide semiconductor layer, contacting the first region and the first oxide semiconductor layer, and containing an oxide conductor.

7. The semiconductor memory device of claim 6, wherein the second region surrounds at least a portion of the first region in a cross section perpendicular to the first direction.

8. The semiconductor memory device of claim 6, wherein the second region contains at least one metal element selected from a group comprising indium (In), gallium (Ga), zinc (Zn), magnesium (Mg), aluminum (Al), manganese (Mn), tin (Sn), titanium (Ti), tantalum (Ta), calcium (Ca), tungsten (W), and molybdenum (Mo), and oxygen (O).

9. The semiconductor memory device of claim 6, wherein the second region is polycrystalline, and [111] directions of a plurality of crystals contained in the second region are oriented in the first direction.

10. The semiconductor memory device of claim 6, wherein the first region contains at least one metal element selected from a group comprising titanium (Ti), tantalum (Ta), tungsten (W), and molybdenum (Mo), and nitrogen (N).

11. The semiconductor memory device of claim 1, wherein the first electrode surrounds the second electrode in a cross section perpendicular to the first direction.

12. The semiconductor memory device of claim 1, wherein the second electrode surrounds the first electrode in a cross section perpendicular to the first direction.

13. The semiconductor memory device of claim 1, further comprising a first insulating layer that is provided between the second electrode and the first gate electrode and contacting the second electrode,
wherein the first insulating layer surrounds the first oxide semiconductor layer in a cross section perpendicular to the first direction.

14. The semiconductor memory device of claim 13, wherein the first insulating layer contains silicon nitride or aluminum oxide.

15. The semiconductor memory device of claim 1, further comprising:
a second capacitor comprising a fourth electrode and a second capacitor insulating film provided between the first electrode and the fourth electrode; and
a second transistor comprising a second oxide semiconductor layer electrically connected to the fourth electrode and extending in the first direction, a second gate electrode provided next to the second oxide semiconductor layer, a second gate insulating film provided between the second gate electrode and the second oxide semiconductor layer, and a fifth electrode electrically connected to the second oxide semiconductor layer and provided with the second oxide semiconductor layer provided between the fourth electrode and the fifth electrode;
wherein the fourth electrode comprises a fourth portion, a fifth portion provided between the fourth portion and the second oxide semiconductor layer, and a sixth portion provided between the fifth portion and the second oxide semiconductor layer;
wherein a fourth width of the fourth portion in the second direction is smaller than a fifth width of the fifth portion in the second direction; and
wherein a sixth width of the sixth portion in the second direction is smaller than the fifth width.

16. The semiconductor memory device of claim 15, wherein a shortest distance between the second electrode and the fourth electrode in the second direction is smaller than the first width and the fourth width.

17. A semiconductor memory system, comprising:
a memory cell array forming a plurality of memory cells, at least one memory cell comprising:
a first capacitor comprising a first electrode, a second electrode, and a first capacitor insulating film provided between the first electrode and the second electrode; and
a first transistor comprising a first oxide semiconductor layer electrically connected to the second electrode and extending in a first direction, a first gate electrode provided next to the first oxide semiconductor layer, a first gate insulating film provided between the first gate electrode and the first oxide semiconductor layer, and a third electrode electrically connected to the first oxide semiconductor layer and provided with the first oxide semiconductor layer between the second electrode and the third electrode;
wherein the second electrode comprises a first portion, a second portion provided between the first portion and the first oxide semiconductor layer, and a third portion provided between the second portion and the first oxide semiconductor layer;
wherein a first width of the first portion in a second direction perpendicular to the first direction is smaller than a second width of the second portion in the second direction; and
wherein a third width of the third portion in the second direction is smaller than the second width.
